(19) United States
(12) Patent Application Publication
(10) Pub. No.: US 2026/0107641 A1
(43) Pub. Date: Apr. 16, 2026

(54) DISPLAY PANEL AND DISPLAY MODULE

(71) Applicants: Hefei Visionox Technology Co., Ltd., Hefei (CN); Kunshan New Flat Panel Display Technology Center Co., Ltd., Kunshan (CN)

(72) Inventors: Hajime Yamaguchi, Hefei (CN); Junhui LOU, Kunshan (CN); PIL-GEUN CHUN, Kunshan (CN); Xiaokang ZHOU, Kunshan (CN)

(73) Assignees: Hefei Visionox Technology Co., Ltd., Hefei (CN); Kunshan New Flat Panel Display Technology Center Co., Ltd., Kunshan (CN)

(21) Appl. No.: 19/356,021

(22) Filed: Oct. 10, 2025

(30) Foreign Application Priority Data
Oct. 12, 2024 (CN) 202411429353.3

(51) Int. Cl. H10K 59/122; G06V 40/13; H10K 39/34; H10K 59/80; H10K 101/40

(52) U.S. Cl. CPC H10K 59/122; H10K 39/34; H10K 59/873; G06V 40/1318; H10K 2101/40

(57) ABSTRACT

Embodiments of the present application provide a display panel and a display module, with the aim of improving the performance of a photo detector in the display panel. An embodiment of a first aspect of the present application provides a display panel. The display panel includes: a substrate; a light-emitting sub-pixel disposed on one side of the substrate, the light-emitting sub-pixel including a light-emitting structure; a photosensitive sub-pixel disposed on one side of the substrate, the photosensitive sub-pixel including a photoelectric sensing structure, a material of the photoelectric sensing structure including a donor material and an acceptor material; and an electron blocking layer disposed on a side of the light-emitting structure and the photoelectric sensing structure facing the substrate, where a HOMO energy level of the donor material is lower than or equal to a HOMO energy level of the electron blocking layer.

### CROSS-REFERENCE TO RELATED APPLICATIONS

The present application claims priority to Chinese Patent Application No. 202411429353.3, filed on Oct. 12, 2024 and entitled “DISPLAY PANEL AND DISPLAY MODULE”, which is incorporated herein by reference in its entirety.

### FIELD

The present application relates to the field of display devices, and particularly to a display panel and a display module.

### BACKGROUND

Biometric recognition plays an important role in smart phones and tablet computers. There are two common methods in the prior art, that is, facial recognition and fingerprint recognition. The fingerprint recognition involves an ultrasonic fingerprint, a capacitive fingerprint, an optical fingerprint, etc. The optical fingerprint has the advantages of high resolution, high sensitivity and the capability of performing life health inspection.

### SUMMARY

Embodiments of the present application provide a display panel and a display module, with the aim of enriching the functionality of the display panel.

An embodiment of a first aspect of the present application provides a display panel. The display panel includes: a substrate; an isolation structure disposed on one side of the substrate, the isolation structure enclosing isolation openings, the isolation openings including a first isolation opening and a second isolation opening; a light-emitting sub-pixel including a light-emitting structure located in the first isolation opening; and a photosensitive sub-pixel including a photoelectric sensing structure located in the second isolation opening.

The display panel further comprising first electrodes and second electrodes, and each of the light-emitting structure and the photoelectric sensing structure is provided with the first electrode on a side facing the substrate, each of the light-emitting structure and the photoelectric sensing structure is provided with the second electrode on a side facing the substrate, and the second electrodes are located in the isolation openings and electrically connected to the isolation structure;

In one embodiment, the isolation structure comprises a first sublayer and a second sublayer located on a side of the first sublayer facing the substrate, an orthographic projection of the first sublayer on the substrate being located within an orthographic projection of the second sublayer on the substrate, and the second electrodes being electrically connected to the first sublayer;

In one embodiment, the isolation structure further comprises a third sublayer located on a side of the first sublayer facing the substrate, the orthographic projection of the first sublayer on the substrate being located within an orthographic projection of the third sublayer on the substrate, and the second electrodes being electrically connected to the third sublayer;

In one embodiment, an inner wall surface of the isolation structure facing the first isolation opening is spaced apart from the light-emitting structure;

In one embodiment, an orthographic projection of the light-emitting structure on the substrate is spaced apart from the orthographic projection of the third sublayer on the substrate; an inner wall surface of the isolation structure facing the second isolation opening is spaced apart from the photoelectric sensing structure.

The display panel further comprises an electron blocking layer disposed on the side of the photoelectric sensing structure facing away from the substrate, the electron blocking layer being divided by the isolation structure into a first section and a second section, the first section being located in the first isolation opening, and the second section being located in the second isolation opening;

In one embodiment, the light-emitting sub-pixel further comprises a hole transport layer located on the side of the light-emitting structure facing the substrate, the first section is located between the hole transport layer and the light-emitting structure, and the second section is located between the first electrode and the photoelectric sensing structure.

The display panel further comprises a hole blocking layer disposed on the side of the photoelectric sensing structure facing the substrate, the hole blocking layer being divided by the isolation structure into a third section and a fourth section, the third section being located in the first isolation opening, and the fourth section being located in the second isolation opening;

In one embodiment, the light-emitting sub-pixel further comprises an electron transport layer on the side of the light-emitting structure facing away from the substrate, the third section is located between the electron transport layer and the light-emitting structure, and the fourth section is located between the second electrode and the photoelectric sensing structure;

In one embodiment, an orthographic projection of the photoelectric sensing structure on the substrate is spaced apart from the orthographic projection of the third sublayer on the substrate;

In one embodiment, a thickness of the second electrode located on the side of the light-emitting structure facing away from the substrate is different from a thickness of the second electrode located on the side of the photoelectric sensing structure facing away from the substrate;

In one embodiment, the first electrode corresponding to the light-emitting structure is configured to transmit a first voltage VL-E, the second electrode corresponding to the light-emitting structure is configured to transmit a second voltage VU-E, the first electrode corresponding to the photoelectric sensing structure is configured to transmit a third voltage VL-P, and the second electrode corresponding to the photoelectric sensing structure is configured to transmit a fourth voltage VU-P, the first voltage, the second voltage, the third voltage and the fourth voltage satisfying the following relationship:

$$VL - E \geq VU - E = VU - P \geq VL - P ;$$

In one embodiment, in the light-emitting structure, holes are moved in a direction from the first electrode to the second electrode, and electrons are moved in a direction from the second electrode to the first electrode; in the photoelectric sensing structure, holes are moved in a direction from the second electrode to the first electrode, and electrons are moved in a direction from the first electrode to the second electrode;

In one embodiment, the light-emitting structure comprises at least one of an organic light-emitting diode material, a quantum dot material, a perovskite material, or a perovskite quantum dot material, and the photoelectric sensing structure comprises at least one of an organic light-emitting diode material, a quantum dot material, a perovskite material, or a perovskite quantum dot material;

In one embodiment, the second electrode corresponding to the light-emitting structure is configured to enable transmission of emitted light from the light-emitting structure, and the second electrode corresponding to the photoelectric sensing structure is configured to enable transmission of sensing light from the photoelectric sensing structure;

In one embodiment, the first electrode corresponding to the light-emitting structure is configured to enable reflection of the emitted light from the light-emitting unit, and the first electrode corresponding to the photoelectric sensing structure is configured to enable reflection of the sensing light from the photoelectric sensing structure; and

In one embodiment, the first electrode comprises a metal oxide layer, a metal layer and a metal oxide layer arranged in a stack.

The display panel further comprising:
a light extraction layer comprising a light extraction portion located on a side of each of the second electrodes facing away from the substrate;
a first encapsulation layer comprising an encapsulation portion located on a side of each of the light extraction portions facing away from the substrate, the plurality of encapsulation portions being disposed separately from each other, and a gap being formed between adjacent encapsulation portions on a side of the isolation structure facing away from the substrate,
In one embodiment, each encapsulation portion comprises a first encapsulation segment and a second encapsulation segment, the first encapsulation segment being located in the respective isolation opening, and the second encapsulation segment being connected to a peripheral side of the first encapsulation segment and located on the side of the isolation structure facing away from the substrate;
In one embodiment, the light extraction layer further comprises a first dummy segment located between each second encapsulation segment and the isolation structure;
In one embodiment, a second dummy segment is further provided between each second encapsulation segment and the isolation structure, the second dummy segment being located between the respective first dummy segment and the isolation structure, and the second dummy segment being of the same material as the light-emitting structure or the photoelectric sensing structure;
In one embodiment, a dummy electrode is further provided between each second dummy segment and the respective first dummy segment, the dummy electrode being of the same material as the second electrode; and
In one embodiment, the light extraction portions comprise a first light extraction portion located on the side of the light-emitting structure facing away from the substrate and a second light extraction portion located on the side of the photoelectric sensing structure facing away from the substrate, a thickness of the first light extraction portion being different from a thickness of the second light extraction portion;
In one embodiment, a second encapsulation layer located on a side of the first encapsulation layer facing away from the substrate, a material of the second encapsulation layer comprising an organic material; and
In one embodiment, a third encapsulation layer located on a side of the second encapsulation layer facing away from the first encapsulation layer, a material of the third encapsulation layer comprising an inorganic material; and
In one embodiment, a material of the first encapsulation layer comprising an inorganic material.

The display panel further comprising: filter portions located on the side of the first encapsulation layer facing away from the substrate, the filter portions comprising a first filter portion and a second filter portion, an orthographic projection of the first filter portion on the substrate at least partially overlapping an orthographic projection of the light-emitting sub-pixel on the substrate, and an orthographic projection of the second filter portion on the substrate at least partially overlapping an orthographic projection of the photosensitive sub-pixel on the substrate,
and the second filter portion comprises a first subunit and a second subunit, the first subunit and the second subunit having at least partially different light transmission wavelength bands;
In one embodiment, photosensitive spectral characteristics of a plurality of photosensitive sub-pixels are the same, and at least two of the photosensitive sub-pixels disposed corresponding to the first subunit and the second subunit, respectively; and
In one embodiment, the photosensitive sub-pixel comprises a first photosensitive unit and a second photosensitive unit, an orthographic projection of the first subunit on the substrate at least partially overlapping an orthographic projection of the first photosensitive unit on the substrate, an orthographic projection of the second subunit on the substrate at least partially overlapping an orthographic projection of the second photosensitive unit on the substrate, the first photosensitive unit and the second photosensitive unit having different photosensitive wavelengths, the light transmission wavelength band of the first subunit at least partially overlapping a photosensitive wavelength band of the first photosensitive unit, and the light transmission wavelength band of the second subunit at least partially overlapping a photosensitive wavelength band of the second photosensitive unit; and
In one embodiment, a first light shielding layer enclosing filter openings in which
the filter portions are located,
In one embodiment, the first filter portion corresponding to the light-emitting sub-pixel is configured to transmit at least part of emitted light from the light-emitting sub-pixel; and
In one embodiment, the second filter portion corresponding to the photosensitive sub-pixel is configured to transmit at least part of sensing light from the photosensitive sub-pixel.

The first subunit of the display panel is configured to transmit green light, and the second subunit is configured to transmit red light;
preferably, the number m of first subunits and the number n of second subunits satisfy: m≥2n; and
an area of the orthographic projection of the first subunit on the substrate is less than or equal to an area of the orthographic projection of the second subunit on the substrate.

The first subunit is configured to transmit red light, and the second subunit is configured to transmit infrared light;
preferably, the number p of first subunits and the number q of second subunits satisfy: p≤2q; and
In one embodiment, an area of the orthographic projection of the first subunit on the substrate is less than or equal to an area of the orthographic projection of the second subunit on the substrate.

The display panel further comprising: a light adjustment layer located on the side of the first encapsulation layer facing away from the substrate, the light adjustment layer comprising a first adjustment layer, the first adjustment layer comprising a first adjustment protrusion and a second adjustment protrusion, an orthographic projection of the first adjustment protrusion on the substrate at least partially overlapping an orthographic projection of the light-emitting sub-pixel on the substrate, and an orthographic projection of the second adjustment protrusion on the substrate at least partially overlapping the orthographic projection of the photoelectric sensing structure on the substrate,
In one embodiment, orthographic projections of a plurality of first adjustment protrusions on the substrate at least partially overlap the orthographic projection of the same light-emitting sub-pixel on the substrate; and
In one embodiment, the second adjustment protrusion is disposed corresponding to the photoelectric sensing structure on a one-to-one basis, and a center of the orthographic projection of the adjustment protrusion on the substrate overlaps a center of the orthographic projection of the photoelectric sensing structure on the substrate; and
In one embodiment, a light protection layer disposed on a side of the light adjustment layer facing away from the substrate, a refractive index of the light protection layer being less than a refractive index of the light adjustment layer,
In one embodiment, the refractive index of the light adjustment layer is greater than 1.5; and
In one embodiment, the refractive index of the light protection layer is less than 1.5.

The display panel further comprising: a second light shielding layer located on the side of the first encapsulation layer facing away from the substrate, the second light shielding layer comprising a first light shielding opening and a second light shielding opening, an orthographic projection of the first light shielding opening on the substrate at least partially overlapping an orthographic projection of the light-emitting structure on the substrate, an orthographic projection of the second light shielding opening on the substrate at least partially overlapping the orthographic projection of the photoelectric sensing structure on the substrate, and an area of the first light shielding opening being greater than an area of the second light shielding opening,
In one embodiment, the second light shielding layer doubles as a touch electrode;
In one embodiment, the orthographic projection of the first light shielding opening on the substrate is quadrilateral; and
In one embodiment, the orthographic projection of the second light shielding opening on the substrate has a circular, elliptical, or near-circular shape.

An embodiment of the first aspect of the present application provides a display panel. The display panel includes: a substrate; a light-emitting sub-pixel disposed on one side of the substrate, the light-emitting sub-pixel including a light-emitting structure; a photosensitive sub-pixel disposed on one side of the substrate, the photosensitive sub-pixel including a photoelectric sensing structure, a material of the photoelectric sensing structure including a donor material and an acceptor material; and an electron blocking layer disposed on a side of the light-emitting structure and the photoelectric sensing structure facing the substrate, where a HOMO energy level of the donor material is lower than or equal to a HOMO energy level of the electron blocking layer.

In one embodiment, at least part of the electron blocking layer is located in the second isolation opening;
In one embodiment, the HOMO energy level of the electron blocking layer is higher than or equal to a HOMO energy level of the light-emitting structure;
In one embodiment, the electron blocking layer is located on a side of the first electrode facing away from the substrate;
In one embodiment, the light-emitting sub-pixel further comprises a hole transport layer located on the side of the light-emitting structure facing the substrate, and the electron blocking layer comprises a first section and a second section, the first section being located between the hole transport layer and the light-emitting structure, and the second section being located between the first electrode and the photoelectric sensing structure;
In one embodiment, the first section and the second section are separated by the isolation structure, the first section is located in the first isolation opening, and the second section is located in the second isolation opening;
In one embodiment, the second section is in contact connection with the first electrode;
In one embodiment, a LUMO energy level of the hole transport layer is lower than a LUMO energy level of the electron blocking layer;
In one embodiment, a HOMO energy level of the hole transport layer is higher than the HOMO energy level of the electron blocking layer;
In one embodiment, the LUMO energy level of the electron blocking layer is higher than a LUMO energy level of the donor material;
In one embodiment, the HOMO energy level of the electron blocking layer is higher than the HOMO energy level of the donor material;
In one embodiment, the light-emitting structure comprises a host material and a dopant material, the dopant material is present in an amount of 0.01% to 10% relative to the host material;
In one embodiment, a doping ratio of the donor material to the acceptor material ranges from 20/1 to 1/20; and
In one embodiment, the acceptor material comprises fullerene or a fullerene derivative.

The display panel according to claim 9, further comprising a hole blocking layer disposed on the side of the photoelectric sensing structure facing the substrate, and a LUMO energy level of the hole blocking layer is higher than or equal to an energy level of the acceptor material;
In one embodiment, the LUMO energy level of the hole blocking layer is lower than or equal to the LUMO energy level of the donor material;
In one embodiment, the light-emitting sub-pixel further comprises an electron transport layer on the side of the light-emitting structure facing away from the substrate, and the hole blocking layer comprises a third section and a fourth section, the third section being located between the electron transport layer and the light-emitting structure, and the fourth section being located between the second electrode and the photoelectric sensing structure;
In one embodiment, the third section and the fourth section are separated by the isolation structure, the third section is located in the first isolation opening, and the fourth section is located in the second isolation opening;
In one embodiment, the fourth section is in contact connection with the second electrode;
In one embodiment, a LUMO energy level of the electron transport layer is lower than the LUMO energy level of the hole blocking layer;
In one embodiment, a HOMO energy level of the electron transport layer is higher than a HOMO energy level of the hole blocking layer;
In one embodiment, the LUMO energy level of the hole blocking layer is lower than a LUMO energy level of the acceptor material; and
In one embodiment, the HOMO energy level of the hole blocking layer is lower than a HOMO energy level of the acceptor material.
The photosensitive sub-pixel further comprises an electron extraction layer located between the photoelectric sensing structure and the hole blocking layer;
In one embodiment, a LUMO energy level of the electron extraction layer is higher than the LUMO energy level of the hole blocking layer;
In one embodiment, a HOMO energy level of the electron extraction layer is higher than the HOMO energy level of the hole blocking layer;
In one embodiment, the LUMO energy level of the electron extraction layer is lower than the LUMO energy level of the acceptor material; and
In one embodiment, the HOMO energy level of the electron extraction layer is lower than the HOMO energy level of the acceptor material.

The display panel according to claim 9, and the photosensitive sub-pixel further comprises a hole extraction layer located between the electron blocking layer and the photoelectric sensing structure;
In one embodiment, the LUMO energy level of the electron blocking layer is higher than a LUMO energy level of the hole extraction layer;
In one embodiment, the HOMO energy level of the electron blocking layer is higher than a HOMO energy level of the hole extraction layer;
In one embodiment, the LUMO energy level of the hole extraction layer is lower than the LUMO energy level of the donor material; and
In one embodiment, the HOMO energy level of the HEL is higher than the HOMO energy level of the donor material.

An area of an orthographic projection of the first isolation opening on the substrate is greater than an area of an orthographic projection of the second isolation opening on the substrate;
and/or the isolation structure comprises a first isolation portion which encloses the first isolation opening and a second isolation portion which encloses the second isolation opening, a width of an orthographic projection of at least part of the first isolation portion on the substrate being smaller than a width of an orthographic projection of the second isolation portion on the substrate.

The display panel further comprising: a pixel definition layer disposed on the substrate, and the isolation structure is disposed on a side of the pixel definition layer facing away from the substrate, and the pixel definition layer comprises a pixel defining portion and a first opening and a second opening provided in the pixel defining portion, the first opening being in communication with the first isolation opening, the second opening being in communication with the second isolation opening, at least part of the light-emitting structure being located in the first opening, and at least part of the photoelectric sensing structure being located in the second opening; and
In one embodiment, first electrodes and second electrodes, and each of the light-emitting structure and the photoelectric sensing structure is provided with the first electrode on a side facing the substrate, each of the light-emitting structure and the photoelectric sensing structure is provided with the second electrode on a side facing away from the substrate, the pixel defining portion covers part of each first electrode, and part of the first electrode is exposed by the first opening and the second opening; and
In one embodiment, in the first isolation opening and in the first opening located within the first isolation opening, a minimum distance between a wall surface of the pixel defining portion facing the first opening and a wall surface of the isolation structure facing the first isolation opening is defined as a first distance d1, and in the second isolation opening and the second opening located within the second isolation opening, a minimum distance between a wall surface of the pixel defining portion facing the second opening and a wall surface of the isolation structure facing the second isolation opening is defined as a second distance d2, the first distance and the second distance satisfying:

$$2 / 3 d 2 \leq d 1 \leq 3 / 2 d 2.$$

A driving module is provided in the substrate, the driving module comprising a first driving unit for driving the light-emitting sub-pixel and a second driving unit for driving the photosensitive sub-pixel, the first driving unit comprising a polysilicon transistor and an oxide transistor, and the second driving unit comprising an oxide transistor.

A photosensitive wavelength band of the photoelectric sensing structure at least partially overlaps a light-emitting wavelength band of the light-emitting structure;
or the display panel further comprises a sensing light-emitting sub-pixel configured to emit sensing light, and the photosensitive sub-pixel is configured to sense the sensing light;
In one embodiment, the light-emitting sub-pixel comprises a red light-emitting sub-pixel, a green light-emitting sub-pixel, and a blue light-emitting sub-pixel, and the photoelectric sensing structure is configured to sense at least one of red light, green light, and blue light; and
In one embodiment, the sensing light-emitting sub-pixel is configured to emit infrared light, and the photosensitive sub-pixel is configured to sense the infrared light.

At least two photosensitive sub-pixels are configured to sense light of different wavelength bands.

A display panel, comprising: a substrate; a light-emitting sub-pixel disposed on one side of the substrate, the light-emitting sub-pixel comprising a light-emitting structure; a photosensitive sub-pixel disposed on one side of the substrate, the photosensitive sub-pixel comprising a photoelectric sensing structure, a material of the photoelectric sensing structure comprising a donor material and an acceptor material; and an electron blocking layer disposed on a side of the light-emitting structure and the photoelectric sensing structure facing the substrate, and a HOMO energy level of the donor material is lower than or equal to a HOMO energy level of the electron blocking layer.

The HOMO energy level of the electron blocking layer is higher than or equal to a HOMO energy level of the light-emitting structure.

The display panel further comprising first electrodes and second electrodes, and each of the light-emitting structure and the photoelectric sensing structure is provided with the first electrode on a side facing the substrate, each of the light-emitting structure and the photoelectric sensing structure is provided with the second electrode on a side facing away from the substrate, and the electron blocking layer is located on a side of the first electrodes facing away from the substrate;
In one embodiment, the light-emitting sub-pixel further comprises a hole transport layer located on the side of the light-emitting structure facing the substrate, and the electron blocking layer comprises a first section and a second section, the first section being located between the hole transport layer and the light-emitting structure, and the second section being located between the first electrode and the photoelectric sensing structure;
In one embodiment, the second section is in contact connection with the first electrode;
In one embodiment, a LUMO energy level of the hole transport layer is lower than a LUMO energy level of the electron blocking layer;
In one embodiment, a HOMO energy level of the hole transport layer is higher than the HOMO energy level of the electron blocking layer;
In one embodiment, the LUMO energy level of the electron blocking layer is higher than a LUMO energy level of the donor material; and
In one embodiment, the HOMO energy level of the electron blocking layer is higher than the HOMO energy level of the donor material.

The display panel further comprising a hole blocking layer disposed on the side of the light-emitting structure and the photoelectric sensing structure facing away from the substrate, and a LUMO energy level of the hole blocking layer is lower than or equal to a LUMO energy level of the donor material; and
In one embodiment, the LUMO energy level of the hole blocking layer is lower than or equal to the LUMO energy level of the donor material.

The light-emitting sub-pixel further comprises an electron transport layer on the side of the light-emitting structure facing away from the substrate, and the hole blocking layer comprises a third section and a fourth section, the third section being located between the electron transport layer and the light-emitting structure, and the fourth section being located between the second electrode and the photoelectric sensing structure;
In one embodiment, the fourth section is in contact connection with the second electrode;
In one embodiment, a LUMO energy level of the electron transport layer is lower than the LUMO energy level of the hole blocking layer;
In one embodiment, a HOMO energy level of the electron transport layer is higher than a HOMO energy level of the hole blocking layer;
In one embodiment, the LUMO energy level of the hole blocking layer is lower than the LUMO energy level of the acceptor material; and
In one embodiment, the HOMO energy level of the hole blocking layer is lower than a HOMO energy level of the acceptor material.
The photosensitive sub-pixel further comprises an electron extraction layer located between the photoelectric sensing structure and the hole blocking layer;
In one embodiment, a LUMO energy level of the electron extraction layer is higher than the LUMO energy level of the hole blocking layer;
In one embodiment, a HOMO energy level of the electron extraction layer is higher than a HOMO energy level of the hole blocking layer;
In one embodiment, the LUMO energy level of the electron extraction layer is lower than the LUMO energy level of the acceptor material; and
In one embodiment, the HOMO energy level of the electron extraction layer is lower than a HOMO energy level of the acceptor material.

The photosensitive sub-pixel further comprises a hole extraction layer located between the electron blocking layer and the photoelectric sensing structure;
In one embodiment, a LUMO energy level of the electron blocking layer is higher than a LUMO energy level of the hole extraction layer;
In one embodiment, the HOMO energy level of the electron blocking layer is higher than a HOMO energy level of the hole extraction layer;
In one embodiment, the LUMO energy level of the hole extraction layer is lower than a LUMO energy level of the donor material; and
In one embodiment, the HOMO energy level of the hole extraction layer is higher than the HOMO energy level of the donor material.

The light-emitting structure comprises a host material and a dopant material, a doping ratio of the dopant material to the host material ranging from 0.1% to 1%.

A ratio of the donor material to the acceptor material ranges from 5/1 to 1/5.

The acceptor material comprises fullerene or a fullerene derivative.

An embodiment of the first aspect of the present application provides a display panel. The display panel includes: a substrate; a light-emitting functional layer disposed on one side of the substrate, the light-emitting functional layer including a light-emitting structure and a photoelectric sensing structure, a material of the photoelectric sensing structure including a donor material and an acceptor material; and a hole blocking layer disposed on a side of the light-emitting functional layer facing the substrate, a HOMO energy level of the hole blocking layer being lower than or equal to an energy level of the acceptor material, and/or a LUMO energy level of the hole blocking layer being lower than or equal to an energy level of the acceptor material.

An embodiment of a second aspect of the present application further provides a display module, including the display panel according to any one of the above embodiments of the first aspect.

An embodiment of the second aspect of the present application further provides a display module, including: a substrate; a pixel unit disposed on the substrate and including a light-emitting sub-pixel and a photosensitive sub-pixel; and filter portions located on a side of the pixel unit facing away from the substrate, the filter portions including a first filter portion and a second filter portion, an orthographic projection of the first filter portion on the substrate at least partially overlapping an orthographic projection of the light-emitting sub-pixel on the substrate, and an orthographic projection of the second filter portion on the substrate at least partially overlapping an orthographic projection of the photosensitive sub-pixel on the substrate, where the second filter portion includes a first subunit and a second subunit, the first subunit and the second subunit having at least partially different light transmission wavelength bands.

The display module further comprising: an encapsulation layer located on a side of the light-emitting structure and the photoelectric sensing structure facing away from the substrate;
a second light shielding layer located on the side of the encapsulation layer facing away from the substrate, the second light shielding layer comprising a first light shielding opening and a second light shielding opening, an orthographic projection of the first light shielding opening on the substrate at least partially overlapping an orthographic projection of the light-emitting structure on the substrate, an orthographic projection of the second light shielding opening on the substrate at least partially overlapping the orthographic projection of the photoelectric sensing structure on the substrate, and an area of the first light shielding opening being greater than an area of the second light shielding opening,
In one embodiment, the light shielding layer doubles as a touch electrode;
In one embodiment, the orthographic projection of the first light shielding opening on the substrate has a polygonal shape; and
In one embodiment, the orthographic projection of the second light shielding opening on the substrate has a circular, elliptical, or near-circular shape.

The display module further comprising: a light adjustment layer located on the side of the first light shielding layer facing away from the substrate, the light adjustment layer comprising a first adjustment layer, the first adjustment layer comprising a first adjustment protrusion and a second adjustment protrusion, an orthographic projection of the first adjustment protrusion on the substrate at least partially overlapping an orthographic projection of the light-emitting sub-pixel on the substrate, and an orthographic projection of the second adjustment protrusion on the substrate at least partially overlapping the orthographic projection of the photoelectric sensing structure on the substrate,
In one embodiment, orthographic projections of a plurality of first adjustment protrusions on the substrate at least partially overlap the orthographic projection of the same light-emitting sub-pixel on the substrate;
In one embodiment, the second adjustment protrusion is disposed corresponding to the photoelectric sensing structure on a one-to-one basis, and a center of the orthographic projection of the adjustment protrusion on the substrate overlaps a center of the orthographic projection of the photoelectric sensing structure on the substrate; and/or the center of the orthographic projection of the adjustment protrusion on the substrate overlaps a center of the orthographic projection of the second light shielding opening on the substrate; and
In one embodiment, a light protection layer disposed on a side of the light adjustment layer facing away from the substrate, a refractive index of the light protection layer being less than a refractive index of the light adjustment layer,
and, preferably, the refractive index of the light adjustment layer is greater than 1.55; and
Preferably, the refractive index of the light protection layer is less than 1.4.

A display module, comprising: a substrate; a pixel unit disposed on the substrate and comprising a light-emitting sub-pixel and a photosensitive sub-pixel; and filter portions located on a side of the pixel unit facing away from the substrate, the filter portions comprising a first filter portion and a second filter portion, an orthographic projection of the first filter portion on the substrate at least partially overlapping an orthographic projection of the light-emitting sub-pixel on the substrate, and an orthographic projection of the second filter portion on the substrate at least partially overlapping an orthographic projection of the photosensitive sub-pixel on the substrate,
In one embodiment, the second filter portion comprises a first subunit and a second subunit, the first subunit and the second subunit having at least partially different light transmission wavelength bands.

The photosensitive sub-pixel comprises a first photosensitive unit and a second photosensitive unit, an orthographic projection of the first subunit on the substrate at least partially overlapping an orthographic projection of the first photosensitive unit on the substrate, an orthographic projection of the second subunit on the substrate at least partially overlapping an orthographic projection of the second photosensitive unit on the substrate, the first photosensitive unit and the second photosensitive unit having different photosensitive wavelengths, the light transmission wavelength band of the first subunit at least partially overlapping a photosensitive wavelength band of the first photosensitive unit, and the light transmission wavelength band of the second subunit at least partially overlapping a photosensitive wavelength band of the second photosensitive unit.

The first subunit is configured to transmit green light, and the second subunit is configured to transmit red light;
In one embodiment, the number m of first subunits and the number n of second subunits satisfy: m≥10n; and
In one embodiment, an area of the orthographic projection of the first subunit on the substrate is less than or equal to an area of the orthographic projection of the second subunit on the substrate.

The first subunit is configured to transmit red light, and the second subunit is configured to transmit infrared light;
In one embodiment, the number p of first subunits and the number q of second subunits satisfy: p≤10q; and
In one embodiment, an area of the orthographic projection of the first subunit on the substrate is less than or equal to an area of the orthographic projection of the second subunit on the substrate.

In the display panel according to the embodiments of the present application, the display panel includes the substrate, the isolation structure, the light-emitting sub-pixel and the photosensitive sub-pixel, where the isolation structure encloses the first isolation opening and the second isolation opening, the light-emitting structure of the light-emitting sub-pixel is located in the first isolation opening, and the photoelectric sensing structure of the photosensitive sub-pixel is located in the second isolation opening, and the mutual interference problem between the light-emitting structure and the photoelectric sensing structure can be alleviated. The display panel of the embodiments of the present application includes both the light-emitting sub-pixel and the photosensitive sub-pixel, which can enable both light-emitting display and light sensing, and the functionality of the display panel can be enriched.

### BRIEF DESCRIPTION OF THE DRAWINGS

By reading the following detailed description of non-limiting embodiments made with reference to the drawings, the other features, objectives and advantages of the present application will become more apparent, in which the same or similar features are denoted by the same or similar reference signs.

FIG. 1 is a structural schematic diagram of a display panel according to an embodiment of the present application;

FIG. 2 is a structural schematic partial enlarged view of FIG. 1 with a pixel unit included;

FIG. 3 is a partial cross-sectional view of FIG. 2;

FIG. 4 is a structural schematic partial enlarged view of FIG. 3 at one position;

FIG. 5 is a structural schematic partial enlarged view of FIG. 3 at another position;

FIG. 6 is a structural schematic partial enlarged view of FIG. 3 at still another position;

FIG. 7 is a cross-sectional view of a display panel according to an embodiment of the present application;

FIG. 8 is another cross-sectional view of a display panel according to an embodiment of the present application;

FIG. 9 is a structural schematic diagram of a circuit of a first driving unit of a display panel according to an embodiment of the present application;

FIG. 10 is a structural schematic diagram of a circuit of a second driving unit of a display panel according to an embodiment of the present application;

FIG. 11 is a spectrum diagram of a light-emitting sub-pixel of a display panel according to an embodiment of the present application;

FIGS. 12 to 14 are photosensitive spectrum diagrams of a photosensitive sub-pixel of a display panel according to various embodiments of the present application;

FIG. 15 is a structural schematic diagram of a pixel unit of a display panel according to another embodiment of the present application;

FIG. 16 is a spectrum diagram of a light-emitting sub-pixel of a display panel according to another embodiment of the present application;

FIGS. 17 to 19 are photosensitive spectrum diagrams of a photosensitive sub-pixel of a display panel according to various embodiments of the present application;

FIG. 20 is a partial cross-sectional view of FIG. 2 according to another embodiment;

FIG. 21 is a structural schematic diagram of a second light shielding layer according to an example;

FIG. 22 is a structural schematic diagram of a second light shielding layer according to another example;

FIG. 23 is a structural schematic diagram of a filter portion according to an example;

FIG. 24 is a structural schematic diagram of a filter portion according to another example;

FIG. 25 is a structural schematic diagram of a light adjustment layer according to an example;

FIG. 26 is a structural schematic diagram of a light adjustment layer according to another example;

FIG. 27 is a structural schematic diagram of a film layer of a display panel according to an example;

FIG. 28 is a structural schematic diagram of an energy level of a light-emitting sub-pixel according to an example;

FIG. 29 is a structural schematic diagram of an energy level of a photosensitive sub-pixel according to an example;

FIG. 30 is a structural schematic diagram of a display module in a use state according to an example;

FIG. 31 is a structural schematic diagram of a display module in a use state according to another example; and

FIGS. 32 and 33 are structural diagrams of detection results of the display module according to various examples.

### DETAILED DESCRIPTION OF THE EMBODIMENTS

Biometric recognition plays an important role in mobile terminals such as smart phones and tablet computers. There are two common methods in the prior art, that is, facial recognition and fingerprint recognition. The fingerprint recognition involves an ultrasonic fingerprint, a capacitive fingerprint, an optical fingerprint, etc. The optical fingerprint has become the mainstream technical means thanks to its advantages of high resolution, high sensitivity and the capability of performing life health inspection.

A larger integrated area and a thinner overall thickness can be achieved by jointly integrating organic light-emitting diodes and photosensors in the panel. An organic photo detector (OPD) prepared on the basis of an organic photosensitive material is compatible with a vacuum evaporation process for an organic light-emitting diode (OLED), which is an important direction for integrating fingerprint recognition into a panel in the future.

By integrating an OPD photosensor into an OLED display panel, fingerprint images and pulse wave data can be obtained, and a multi-function display device with biometric recognition and health sensor functions can be realized. To integrate the photosensor into the organic light-emitting display panel, an OPD sub-pixel prepared on the basis of an organic photosensitive material is compatible with a vacuum evaporation process for an OLED sub-pixel, which is an important direction for integrating fingerprint recognition into a panel in the future. It is worrisome that in order to add the OPD sub-pixel, the opening rate of the OLED sub-pixel needs to be reduced, resulting in a reduced lifetime of the OLED display panel. In addition, from the perspective of the display performance of the OLED display panel, there are concerns that achieving high definition and high brightness will be difficult. Furthermore, in view of the mass yield, for layers, such as a hole transport layer 340 (HTL), an electron transport layer 360 (ETL), and a hole blocking layer 350 (HBL), that are made by using a common metal mask (CMM), even the OPD sub-pixel must use the same material and thickness as the OLED sub-pixel. As a result, the energy level relationship between the HOMO levels of the OPD layer and the HBL becomes unstable, and the integrated OPD sensor may have a lower performance and reliability than a separate OPD.

In the OLED display panel industry, in order to solve the above-mentioned problem of precision evaporation process restricting the opening rate and resolution, a method for patterning an OLED sub-pixel using a photolithography machine has been proposed, and trial samples have been produced. Since no precision evaporation process is used, the opening rate can be increased and high definition is expected to be achieved. However, there have been no reported instances of integrated OPD sub-pixels yet.

In the embodiments of the present application, an OLED display panel that can maintain the performance and reliability of the OLED display panel even with the addition of an OPD sub-pixel is provide by integrating the OPD sub-pixel into the OLED display panel using lithography technology. In addition, the performance and reliability of the OPD sub-pixel integrated into the OLED display panel can be improved.

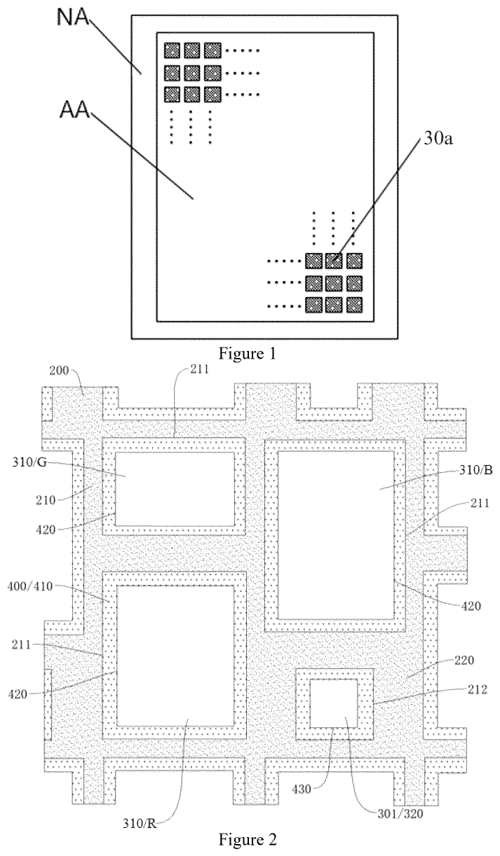

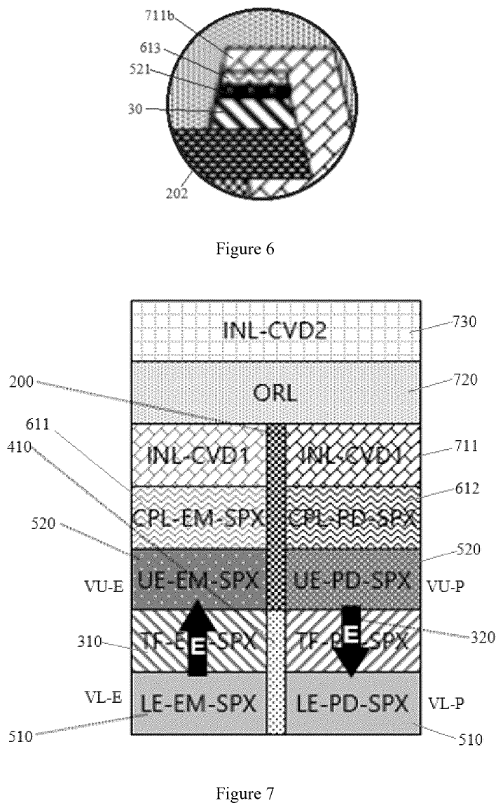

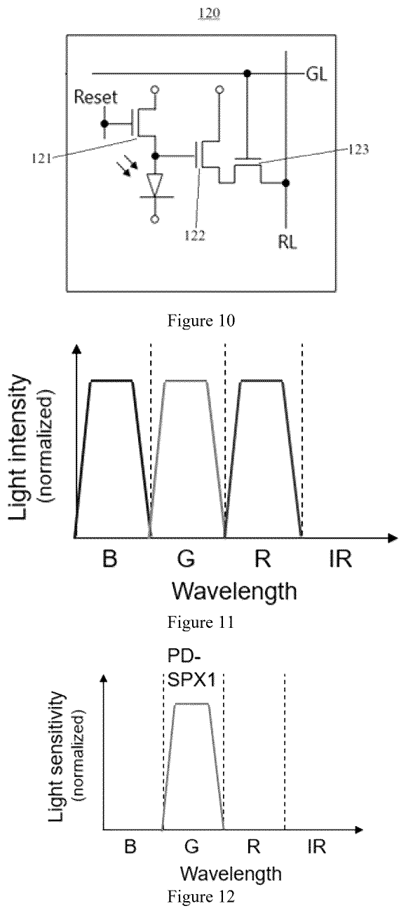

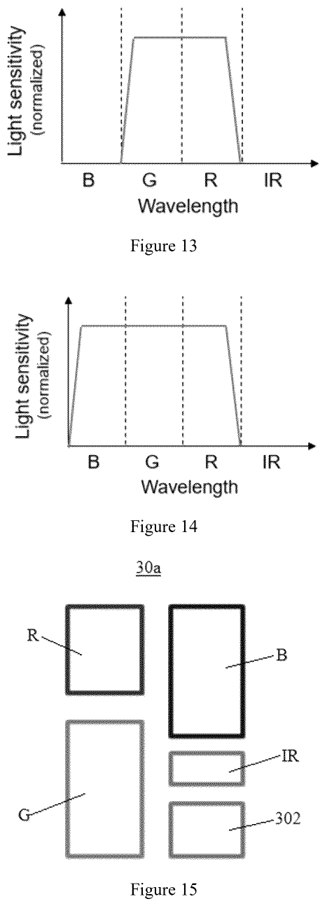

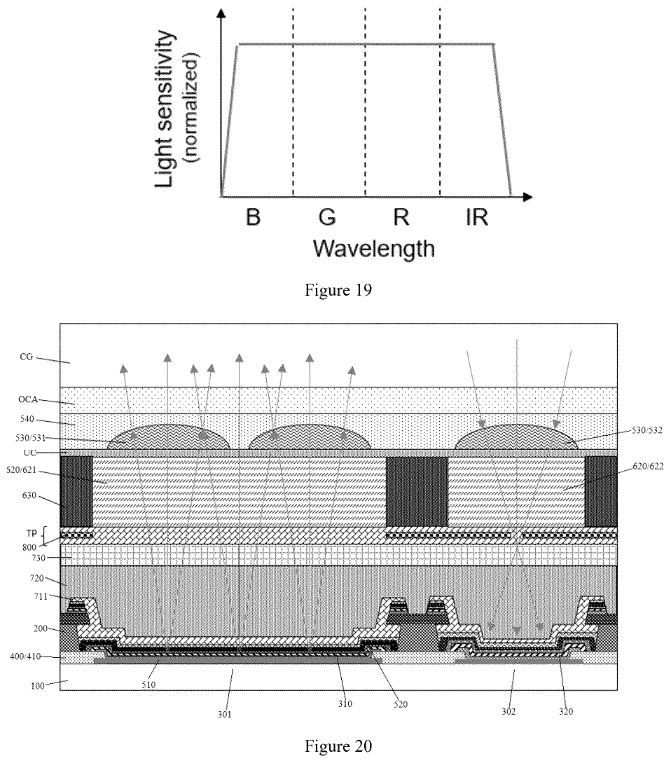

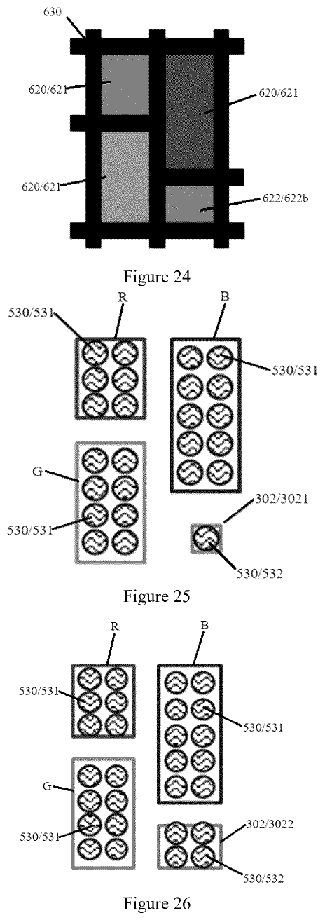

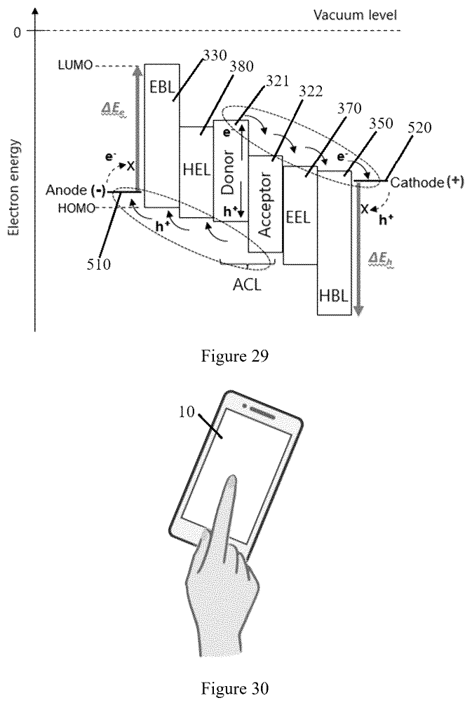

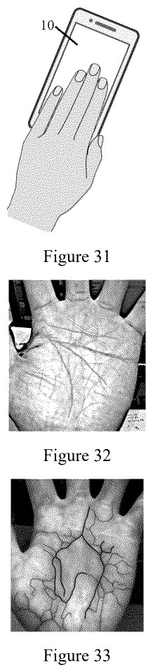

In order to better understand the present application, a display panel and a display module 10 according to the embodiments of the present application will be described below with reference to FIGS. 1 to 33.

Referring to FIGS. 1 to 3 together, an embodiment of a first aspect of the present application further provides a display panel, including: a substrate 100; an isolation structure 200 disposed on one side of the isolation structure 200, the isolation structure 200 enclosing isolation openings 210, the isolation openings 210 including a first isolation opening 211 and a second isolation opening 212; a light-emitting sub-pixel 301 including a light-emitting structure 310 located in the first isolation opening 211; and a photosensitive sub-pixel 302 including a photoelectric sensing structure 320 located in the second isolation opening 212.

In the embodiment of the present application, the display panel includes the substrate 100, the isolation structure 200, the light-emitting sub-pixel 301 and the photosensitive sub-pixel 302, where the isolation structure 200 encloses the first isolation opening 211 and the second isolation opening 212, the light-emitting structure 310 of the light-emitting sub-pixel 301 is located in the first isolation opening 211, and the photoelectric sensing structure 320 of the photosensitive sub-pixel 302 is located in the second isolation opening 212, and the mutual interference problem between the light-emitting structure 310 and the photoelectric sensing structure 320 can be alleviated. The display panel of the embodiment of the present application includes both the light-emitting sub-pixel 301 and the photosensitive sub-pixel 302, which can enable both light-emitting display and light sensing, and the functionality of the display panel can be enriched.

In one embodiment, the display panel includes an active area and a non-active area, and the light-emitting sub-pixel 301 and the photosensitive sub-pixel 302 are located in the active area. In one embodiment, a plurality of light-emitting sub-pixels 301 and a photosensitive sub-pixel 302 may form a pixel unit 30a, and a plurality of pixel units 30a are repeatedly arranged to form the display panel. In one embodiment, the light-emitting sub-pixel 301 may be an OLED sub-pixel as described above, and the photosensitive sub-pixel 302 may be an OPD sub-pixel as described above.

In one embodiment, the light-emitting sub-pixel 301 includes a red sub-pixel R, a green sub-pixel G, and a blue sub-pixel B for color-coded display of the display panel. The pixel unit 30a may include a red sub-pixel R, a green sub-pixel G, a blue sub-pixel B, and a photosensitive sub-pixel 302.

In some embodiments, the display panel further includes a pixel definition layer 400. The pixel definition layer 400 is disposed on the substrate 100, and the isolation structure 200 is disposed on a side of the pixel definition layer 400 facing away from the substrate 100. The pixel definition layer 400 includes a pixel defining portion 410, and a first opening 420 and a second opening 430 provided in the pixel defining portion 410. The first opening 420 is in communication with the first isolation opening 211, and the second opening 430 is in communication with the second isolation opening 212. At least part of the light-emitting structure 310 is located in the first opening 420, and at least part of the photoelectric sensing structure 320 is located in the second opening 430.

In one embodiment, the display panel further includes first electrodes 510 and second electrodes 520. Each of the light-emitting structure 310 and the photoelectric sensing structure 320 is provided with the first electrode 510 on a side facing the substrate 100, and each of the light-emitting structure 310 and the photoelectric sensing structure 320 is provided with the second electrode 520 on a side facing away from the substrate 100.

In one embodiment, the first electrode 510 is located on a side of the pixel definition layer 400 facing the substrate 100, and the first electrode 510 is exposed by a pixel opening and a photosensitive opening. In one embodiment, the pixel defining portion 410 covers part of the first electrode 510, and part of the first electrode 510 is exposed by the first opening 420 and the second opening 430. The pixel defining portion 410 covers part of an edge of the first electrode 510, and it can be ensured that an area of the first electrode 510 exposed by the first opening 420 and the second opening 430 is sufficiently large.

In an embodiment of the present application, the light-emitting sub-pixel 301 may include only the light-emitting structure 310, and the photosensitive sub-pixel 302 may include only the photoelectric sensing structure 320. The first electrode 510 and the second electrode 520 may not be part of the light-emitting sub-pixel 301 and/or the photosensitive sub-pixel 302. In other embodiments, the light-emitting sub-pixel 301 may include a light-emitting structure 310, and a first electrode 510 and a second electrode 520 located on two sides of the light-emitting structure 310, and the photosensitive sub-pixel 302 includes a photoelectric sensing structure 320, and a first electrode 510 and a second electrode 520 located on two sides of the photoelectric sensing structure 320.

In one embodiment, the second electrode 520 is located in the isolation opening 210 and is electrically connected to the isolation structure 200.

In these embodiments, the first electrodes 510 and the second electrodes 520 may drive the light-emitting structure 310 to emit light, and electrons and holes generated in the photoelectric sensing structure 320 may be transported to the first electrode 510 and the second electrode 520, enabling the collection of photoelectric sensing signals. The second electrodes 520 are electrically connected to the isolation structure 200 and a plurality of second electrodes 520 can be interconnected into a planar electrode by means of the isolation structure 200.

In one embodiment, referring to FIGS. 2 to 4 together, the isolation structure 200 includes a first sublayer 201 and a second sublayer 202 on a side of the first sublayer 201 facing away from the substrate 100. An orthographic projection of the first sublayer 201 on the substrate 100 is located within an orthographic projection of the second sublayer 202 on the substrate 100, and the second electrodes 520 are electrically connected to the first sublayer 201.

In these embodiments, the size of the first sublayer 201 may be smaller than the size of the second sublayer 202, and an indentation may be formed under the second sublayer 202. During the preparation of the light-emitting structures 310 or the photoelectric sensing structures 320, a light-emitting material or a photoelectric sensing material is easily broken at an edge of the second sublayer 202 to form the light-emitting structures 310 or the photoelectric sensing structures 320 separate from each other, and the preparation process of the photoelectric sensing structures 320 and the light-emitting structures 310 can be simplified.

In one embodiment, during the preparation of the second electrodes 520, a conductive material for preparing the second electrodes 520 is easily broken at the edge of the second sublayer 202 to form a plurality of second electrodes 520 separate from each other, and the second electrodes 520 are electrically connected to the first sublayer 201, and the plurality of second electrodes 520 can be interconnected into a planar electrode by means of the isolation structure 200.

In one embodiment, an area of the orthographic projection of the first sublayer 201 on the substrate 100 is less than an area of the orthographic projection of the second sublayer 202 on the substrate 100, facilitating the formation of an indentation under the second sublayer 202.

In one embodiment, the isolation structure 200 further includes a third sublayer 203 located on a side of the first sublayer 201 facing the substrate 100. The orthographic projection of the first sublayer 201 on the substrate 100 is located within an orthographic projection of the third sublayer 203 on the substrate 100. The second electrode 520 and the third sublayer 203 are electrically connected to each other.

In these embodiments, by providing the third sublayer 203, the third sublayer 203 may provide protection to a film layer on the side of the substrate 100 when the first sublayer 201 is side-etched and the size of the first sublayer 201 is less than the size of the second sublayer 202. The second electrode 520 being electrically connected to the third sublayer 203 can improve the electrical connection yield of the second electrodes 520 and the isolation structure 200.

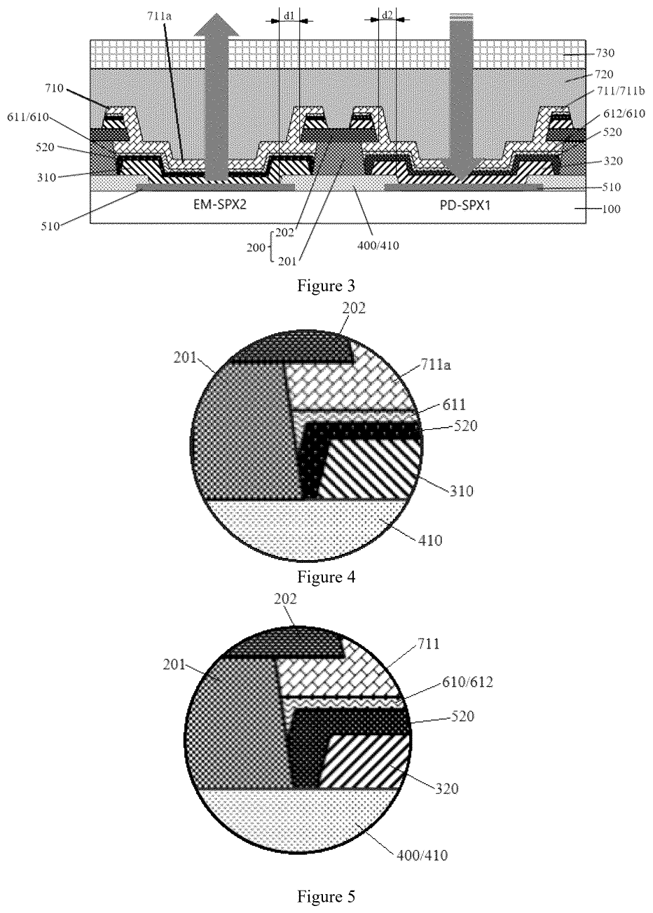

In one embodiment, as shown in FIGS. 3 and 4, an inner wall surface of the isolation structure 200 facing the first isolation opening 211 is spaced apart from the light-emitting structure 310. To improve the contact connection between the light-emitting structure 310 and the isolation structure 200, electrons generated in the light-emitting structure 310 are transferred to the other light-emitting structures 310 through the isolation structure 200, affecting the display effect of the display panel.

In one embodiment, an orthographic projection of the light-emitting structure 310 on the substrate 100 is spaced apart from the orthographic projection of the third sublayer 203 on the substrate 100. In this way, the light-emitting structure 310 and the third sublayer 203 are insulated from each other, thereby improving the transfer of the electrons generated in the light-emitting structure 310 to the other light-emitting structures 310 through the isolation structure 200, and affecting the display effect of the display panel.

In one embodiment, as shown in FIGS. 3 to 5, an inner wall surface of the isolation structure 200 facing the second isolation opening 212 is spaced apart from the photoelectric sensing structure 320. In this way, the photoelectric sensing structure 320 and the isolation structure 200 are insulated from each other, thereby improving the transport of electrons generated in photoelectric sensing structure 320 to the isolation structure 200 and affecting the photoelectric sensing effect.

In one embodiment, an orthographic projection of the photoelectric sensing structure 320 on the substrate 100 is spaced apart from the orthographic projection of the third sublayer 203 on the substrate 100. In this way, the photoelectric sensing structure 320 and the third sublayer 203 are insulated from each other, thereby improving the transport of the electrons generated in photoelectric sensing structure 320 to the third sublayer 203 and affecting the photoelectric sensing effect.

In one embodiment, the display panel further includes an electron blocking layer 330. The electron blocking layer 330 is disposed on the side of the photoelectric sensing structure 320 facing away from the substrate 100. The electron blocking layer 330 is divided by the isolation structure 200 into a first section 331 and a second section 332. The first section 331 is located in the first isolation opening 211, and the second section 332 is located in the second isolation opening 212. Due to the presence of the isolation structure 200, during the preparation of the electron blocking layer 330, the electron blocking layer 330 can be divided into the first section 331 and the second section 332, the first section 331 being located in the first isolation opening 211 is used for improving the light-emitting effect, and the second section 332 being located in the second isolation opening 212 is used for improving the sensing effect.

In one embodiment, the light-emitting sub-pixel 301 further includes a hole transport layer 340 located on the side of the light-emitting structure 310 facing the substrate 100. The first section 331 is located between the hole transport layer 340 and the light-emitting structure 310, and the second section 332 is located between the first electrode 510 and the photoelectric sensing structure 320. The first section 331 being located between the hole transport layer 340 and the light-emitting structure 310 is used for blocking the transport of electrons from the light-emitting structure 310 to the hole transport layer 340. The second section 332 being located between the first electrode 510 photoelectric sensing structures 320 is used for blocking the transport of electrons from the photoelectric sensing structures 320 to the first electrode 510.

In one embodiment, the display panel further includes a hole blocking layer 350 disposed on the side of the photoelectric sensing structure 320 facing the substrate 100. The hole blocking layer 350 is divided by the isolation structure 200 into a third section 351 and a fourth section 352. The third section 351 is located in the first isolation opening 211, and the fourth section 352 is located in the second isolation opening 212. Due to the presence of the isolation structure 200, during the preparation of the hole blocking layer 350, the electron blocking layer 330 can be divided into the third section 351 and the fourth section 352, the third section 351 being located in the first isolation opening 211 is used for improving the light-emitting effect, and the fourth section 352 being located in the second isolation opening 212 is used for improving the sensing effect.

In one embodiment, the light-emitting sub-pixel 301 further includes an electron transport layer 360 located on the side of the light-emitting structure 310 facing away from the substrate 100. The third section 351 is located between the electron transport layer 360 and the light-emitting structure 310, and the fourth section 352 is located between the second electrode 520 and the photoelectric sensing structure 320. The third section 351 being located between the electron transport layer 360 and the light-emitting structure 310 is used for blocking the transport of holes from the light-emitting structure 310 to the electron transport layer 360. The fourth section 352 being located between the second electrode 520 and the photoelectric sensing structure 320 is used for blocking the transport of holes from the photoelectric sensing structure 320 to the second electrode 520.

In one embodiment, a thickness of the second electrode 520 located on the side of the light-emitting structure 310 facing away from the substrate 100 is different from a thickness of the second electrode 520 located on the side of the photoelectric sensing structure 320 facing away from the substrate 100. That is, the thicknesses of the second electrode 520 disposed corresponding to the photoelectric sensing structure 320 and the second electrode 520 disposed corresponding to the light-emitting structure 310 may be different to meet the respective requirements of the light-emitting structure 310 and the photoelectric sensing structure 320 to improve the display effect and the photoelectric sensing effect.

Due to the presence of the isolation structure 200, during the preparation of the light-emitting structure 310 and the photoelectric sensing structure 320, the light-emitting structure 310, the second electrode 520 on the light-emitting structure 310, and the second electrode 520 on the photoelectric sensing structure 320 may be prepared in different process steps, and appropriate thicknesses of the second electrodes 520 can be selected according to the actual use requirements, to meet the respective requirements of the light-emitting structure 310 and the photoelectric sensing structure 320 simultaneously, thereby improving the display effect and the photoelectric sensing effect.

In some embodiments, as shown in FIGS. 2 to 6, the display panel further includes a light extraction layer and a first encapsulation layer 710. The light extraction layer includes a light extraction portion 610 located on a side of each second electrode 520 facing away from the substrate 100. The first encapsulation layer 710 includes an encapsulation portion 711 located on a side of each light extraction portion 610 facing away from the substrate 100. The plurality of encapsulation portions 711 are disposed separately from each other, and a gap is formed between adjacent encapsulation portions 711 on a side of the isolation structure 200 facing away from the substrate 100.

In these embodiments, the second electrode 520 is provided with a light extraction portion 610, which can improve the light extraction effect. The first encapsulation layer 710 includes a plurality of encapsulation portions 711 arranged separately, enabling the separate encapsulation of light-emitting sub-pixels 301 and photosensitive sub-pixels 302, thereby alleviating the problem of moisture transfer between different light-emitting sub-pixels 301 or photosensitive sub-pixels 302.

In one embodiment, the encapsulation portion 711 includes a first encapsulation segment 711a and a second encapsulation segment 711b. The first encapsulation segment 711a is located in the isolation opening 210, and the second encapsulation segment 711b is connected to a peripheral side of the first encapsulation segment 711a and located on the side of the isolation structure 200 facing away from the substrate 100, to increase the distribution area of the encapsulation portion 711, and improve the sealing effect of the encapsulation portion 711.

In one embodiment, as shown in FIGS. 3 to 7, the light extraction layer further includes a first dummy segment 613 located between each second encapsulation segment and the isolation structure 200.

During the preparation of the light-emitting structure 310 of the display panel, it is possible to provide a light-emitting material layer for preparing the light-emitting structure 310, a conductive material layer for preparing the second electrode 520, a light extraction material layer for preparing the light extraction layer, and an encapsulation material layer for preparing the encapsulation portions 711 in sequence on the side of the isolation openings 210 and the isolation structure 200 facing away from the substrate 100, and then pattern the light-emitting material layer, the conductive material layer, the light extraction material layer, and the encapsulation material layer to form the light-emitting structure 310, the second electrode 520, the light extraction portions 610 and the encapsulation portions 711.

During the preparation of the photoelectric sensing structure 320 of the display panel, it is possible to provide a photoelectric material layer for preparing the photoelectric sensing structure 320, a conductive material layer for preparing the second electrode 520, a light extraction material layer for preparing the light extraction layer, and an encapsulation material layer for preparing the encapsulation portions 711 in sequence on the side of the isolation openings 210 and the isolation structure 200 facing away from the substrate 100, and then pattern the photoelectric material layer, the conductive material layer, the light extraction material layer, and the encapsulation material layer to form the photoelectric sensing structure 320, the second electrode 520, the light extraction portions 610 and the encapsulation portions 711.

When preparing the light extraction material layer and the encapsulation material layer, part of the light extraction material layer is disposed on the isolation structure 200 to form the first dummy segment 613.

In one embodiment, a second dummy segment 30 is further provided between each second encapsulation segment and the isolation structure 200. The second dummy segment 30 is located between the first dummy segment 613 and the isolation structure 200, and the second dummy segment 30 is of the same material as the light-emitting structure 310 or the photoelectric sensing structure 320.

As above, when preparing the light-emitting structure 310 or the photoelectric sensing structure 320, part of the light-emitting material layer or the photoelectric material layer is disposed on the isolation structure 200 to form the second dummy segment 30.

In one embodiment, a dummy electrode 521 is further provided between the second dummy segment 30 and the first dummy segment 613, the dummy electrode 521 being of the same material as the second electrode 520. As above, when preparing the second electrode 520, part of the conductive material layer is disposed on the isolation structure 200 to form the dummy electrode 521.

In one embodiment, with continued reference to FIGS. 2 to 6, the light extraction portion 610 includes a first light extraction portion 611 located on the side of the light-emitting structure 310 facing away from the substrate 100 and a second light extraction portion 612 located on the side of the photoelectric sensing structure 320 facing away from the substrate 100. A thickness of the first light extraction portion 611 is different from a thickness of the second light extraction portion 612. The first light extraction portion 611 and the second light extraction portion 612 may be prepared and formed in different process steps, and the thickness of the first light extraction portion 611 is different from the thickness of the second light extraction portion 612 to meet the different requirements of the light-emitting sub-pixel 301 and the photosensitive sub-pixel 302.

In one embodiment, as shown in FIG. 3, the display panel further includes a second encapsulation layer 720. The second encapsulation layer 720 is located on a side of the first encapsulation layer 710 facing away from the substrate 100, and a material of the second encapsulation layer 720 includes an organic material. By providing the second encapsulation layer 720, the overall flatness of the encapsulation layer can be improved.

In one embodiment, the display panel further includes a third encapsulation layer 730. The third encapsulation layer 730 is located on a side of the second encapsulation layer 720 facing away from the first encapsulation layer 710, and a material of the third encapsulation layer 730 includes an inorganic material, to further improve the encapsulation effect.

In one embodiment, the material of the first encapsulation layer 710 includes an inorganic material. In this way, the first encapsulation layer 710 has good compactness, ensuring the sealing effect of the encapsulation portion 711.

In one embodiment, as shown in FIGS. 2 to 7, the first electrode 510 corresponding to the light-emitting structure 310 is configured to transmit a first voltage VL-E, the second electrode 520 corresponding to the light-emitting structure 310 is configured to transmit a second voltage VU-E, the first electrode 510 corresponding to the photoelectric sensing structure 320 is configured to transmit a third voltage VL-P, and the second electrode 520 corresponding to the photoelectric sensing structure 320 is configured to transmit a fourth voltage VU-P, the first voltage, the second voltage, the third voltage and the fourth voltage satisfying the following relationship:

$$VL - E \geq VU - E = VU - P \geq VL - P .$$

In these embodiments, when the first voltage VL-E, the second voltage VU-E, the third voltage VL-P, and the fourth voltage VU-P satisfy the above relationship, the current can flow from the first voltage to the second voltage to drive the light-emitting structure 310 to emit light, and from the fourth voltage to the third voltage, and current signals generated by photoelectric sensing are collected by the first electrode 510 and the second electrode 520.

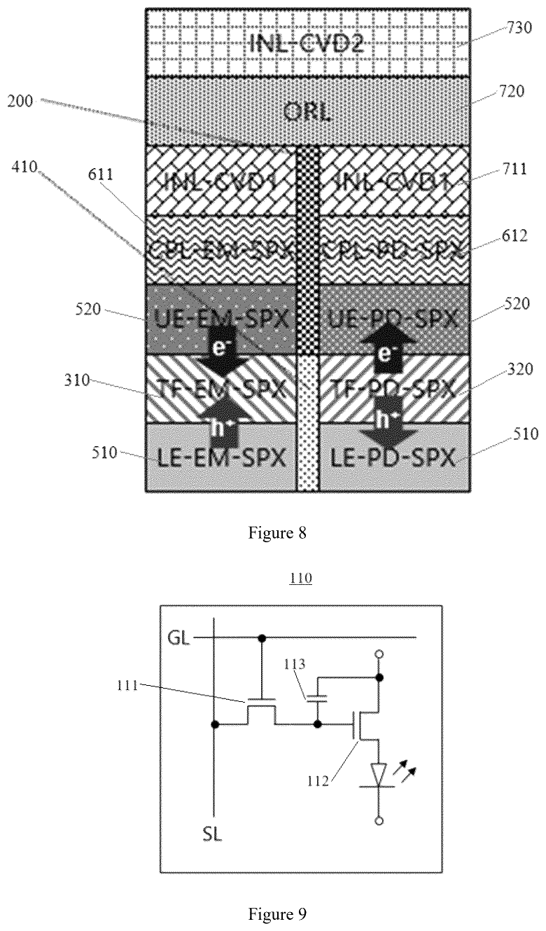

In one embodiment, as shown in FIG. 8, in the light-emitting structure 310, holes (h+) are moved in a direction from the first electrode 510 to the second electrode 520, and electrons (e−) are moved in a direction from the second electrode 520 to the first electrode 510, and the electrons (e−) and the holes (h+) recombine at the light-emitting structure 310 to generate huge energy, driving the light-emitting structure 310 to emit light.

In one embodiment, as shown in FIG. 8, in the photoelectric sensing structure 320, holes (h+) are moved in the direction from the second electrode 520 to the first electrode 510, and electrons (e−) are moved in the direction from the first electrode 510 to the second electrode 520, and the electrons (e−) and the holes (h+) generated by photoelectric sensing can be collected by the first electrode 510 and the second electrode 520.

In one embodiment, the direction of the electric field in the light-emitting sub-pixel 301 is opposite to the direction of the electric field in the photosensitive sub-pixel 302, and the first electrode 510 and the second electrode 520 can drive the light-emitting sub-pixel 301 to emit light, and collect electrical signals generated by photoelectric sensing.

The light-emitting structure 310 and the photoelectric sensing structure 320 may be configured in various ways. In one embodiment, the light-emitting structure 310 includes at least one of an organic light-emitting diode material, a quantum dot material, a perovskite material, or a perovskite quantum dot material, and the photoelectric sensing structure 320 includes at least one of an organic light-emitting diode material, a quantum dot material, a perovskite material, or a perovskite quantum dot material, to meet the different use requirements of the display panel.

In some embodiments, with continued reference to FIG. 2, an area of an orthographic projection of the first isolation opening 211 on the substrate 100 is greater than an area of an orthographic projection of the second isolation opening 212 on the substrate 100, to increase the distribution area of the light-emitting structure 310, ensuring the light-emitting display effect of the display panel.

In one embodiment, the isolation structure 200 includes a first isolation portion 220 which encloses the first isolation opening 211 and a second isolation portion 230 which encloses the second isolation opening 212. A width of an orthographic projection of at least part of the first isolation portion 220 on the substrate 100 is smaller than a width of an orthographic projection of the second isolation portion 230 on the substrate 100. Furthermore, the area of the orthographic projection of the first isolation opening 211 on the substrate 100 is greater than the area of the orthographic projection of the second isolation opening 212 on the substrate 100, to increase the distribution area of the light-emitting structure 310, ensuring the light-emitting display effect of the display panel.

In one embodiment, with continued reference to FIGS. 2 and 3, in the first isolation opening 211 and in the first opening 420 located within the first isolation opening, a minimum distance between a wall surface of the pixel defining portion 410 facing the first opening 420 and a wall surface of the isolation structure 200 facing the first isolation opening 211 is defined as a first distance d1, and in the second isolation opening 212 and the second opening 430 located within the second isolation opening, a minimum distance between a wall surface of the pixel defining portion 410 facing the second opening 430 and a wall surface of the isolation structure 200 facing the second isolation opening 212 is defined as a second distance d2, the first distance and the second distance satisfying: 2/3d2≤d1≤3/2d2.

In these embodiments, the second distance d2 corresponding to photosensitive sub-pixel 302 is close to the first distance d1 corresponding to light-emitting sub-pixel 301, and the photosensitive sub-pixel 302 and the light-emitting sub-pixel 301 can be prepared using similar processes, thereby simplifying the preparation process of the display panel.

In one embodiment, the second electrode 520 corresponding to the light-emitting structure 310 is configured to enable transmission of emitted light from a light-emitting unit to improve the effect of the second electrode 520 on the light emitted from the light-emitting structure 310. In one embodiment, the second electrode 520 corresponding to the photoelectric sensing structure 320 is configured to enable transmission of sensing light from the photoelectric sensing structure 320, to improve the effect of the second electrode 520 on the incidence of light to the photoelectric sensing structure 320.

In one embodiment, the first electrode 510 corresponding to the light-emitting structure 310 is configured to enable reflection of the emitted light from the light-emitting unit, to increase the amount of light emitted from the light-emitting sub-pixel 301, thereby improving the display effect of the display panel. The first electrode 510 corresponding to the photoelectric sensing structure 320 is configured to enable reflection of the sensing light from the photoelectric sensing structure 320, to increase the amount of light incident on the photoelectric sensing structure 320, thereby improving the photosensitive effect of the photoelectric sensing structure 320.

In one embodiment, the first electrode 510 includes a metal oxide layer, a metal layer and a metal oxide layer arranged in a stack. For example, the first electrode 510 include indium tin oxide, silver, and indium tin oxide, and the first electrode 510 has good electrical conductivity and reflective properties.

In some embodiments, referring to FIGS. 1 to 10 together, a driving module 101 is provided in the substrate 100. The driving module 101 includes a first driving unit 110 for driving the light-emitting sub-pixel 301 and a second driving unit 120 for driving the photosensitive sub-pixel 302. The first driving unit 110 includes a polysilicon transistor and an oxide transistor, and the second driving unit 120 includes an oxide transistor.

In one embodiment, the first driving unit 110 includes a switching transistor 111 and a driving transistor 112. The polysilicon transistor may serve as the driving transistor 112, and the oxide transistor may serve as the switching transistor 111. The polysilicon transistor may be a low-temperature polysilicon transistor, and a oxide transistor may be an indium gallium zinc oxide transistor. In one embodiment, the first driving unit 110 may further include a capacitor 113.

In one embodiment, the second driving unit 120 includes a first transistor 121, a second transistor 122 and a third transistor 123. At least one of the first transistor 121, the second transistor 122 and the third transistor 123 is an oxide transistor.

In one embodiment, as above, a plurality of light-emitting sub-pixels 301 and a photosensitive sub-pixel 302 constitute a pixel unit 30a. The light-emitting sub-pixels 301 include a red sub-pixel R, a green sub-pixel G, and a blue sub-pixel B. The pixel unit 30a includes a red sub-pixel R, a green sub-pixel G, a blue sub-pixel B, and a photosensitive sub-pixel 302.

A diagram of the spectral characteristics of the red sub-pixel R, the green sub-pixel G, and the blue sub-pixel B is shown in FIG. 11. FIGS. 12 to 14 are diagrams of the spectral characteristics of the photosensitive wavelength band of the photoelectric sensing structure 320. In some embodiments, as shown in FIGS. 11 to 14, the photosensitive wavelength band of the photoelectric sensing structure 320 at least partially overlaps the light-emitting wavelength band of the light-emitting structure 310. In this way, the light-emitting structure 310 may serve as a light source for the photoelectric sensing structure 320, thereby simplifying the structure of the display panel.

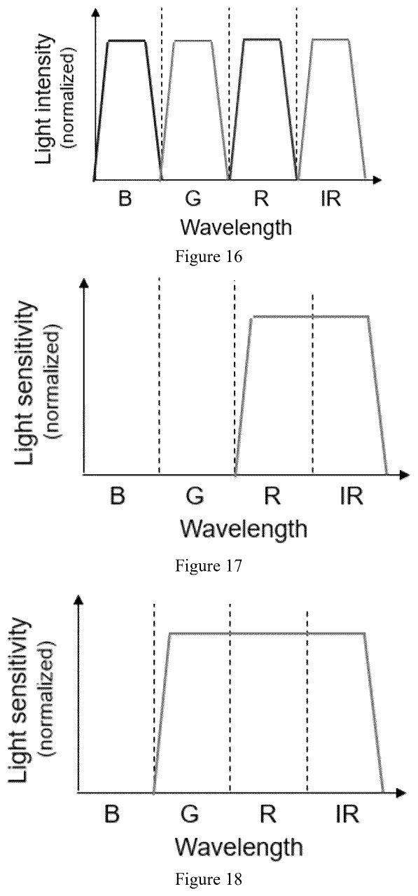

In one embodiment, in some other embodiments, as shown in FIG. 15, the display panel further includes a sensing light-emitting sub-pixel IR. The sensing light-emitting sub-pixel IR is configured to emit sensing light. As shown in FIG. 16, FIG. 16 shows the photosensitive sub-pixel 302 for sensing the sensing light. FIGS. 17 to 19 are diagrams of the photosensitive spectral characteristics of the photosensitive sub-pixel 302 in various embodiments. In one embodiment, the photosensitive sub-pixel 302 is configured to sense the sensing light. In these embodiments, a dedicated light source is provided for the photosensitive sub-pixel 302. In one embodiment, the pixel unit 30a described above includes the sensing light-emitting sub-pixel IR.

In one embodiment, as shown in FIGS. 11 to 19, the light-emitting sub-pixel 301 includes a red light-emitting sub-pixel 301, a green light-emitting sub-pixel 301 and a blue light-emitting sub-pixel 301, and the photoelectric sensing structure 320 is configured to sense at least one of red light, green light, and blue light, and the light-emitting sub-pixel 301 can serve as a light source for the photosensitive sub-pixel 302, thereby simplifying the structure of the display panel.

For example, the photoelectric sensing structure 320 is configured to sense green light. In one embodiment, the photoelectric sensing structure 320 is configured to sense red light and green light. In one embodiment, one of the plurality of photoelectric sensing structures 320 is configured to sense green light and the other is configured to sense red light. In one embodiment, the photoelectric sensing structure 320 is configured to sense red light and infrared light.

In one embodiment, the same pixel unit 30a may include two photosensitive sub-pixels 302 for sensing different colors of light. In one embodiment, the photosensitive sub-pixel 302 of one of the plurality of pixel units 30a is configured to sense green light, and the photosensitive sub-pixel 302 of the other pixel unit is configured to sense red light. That is, two photosensitive sub-pixels 302 with different sensing spectral characteristics are arranged in two different pixel units 30a.

In one embodiment, the sensing light-emitting sub-pixel IR is configured to emit infrared light, and the photosensitive sub-pixel 302 is configured to sense infrared light.

In some embodiments, at least two photosensitive sub-pixels 302 are configured to sense light of different wavelength bands, and the at least two photosensitive sub-pixels 302 are available for different functions.

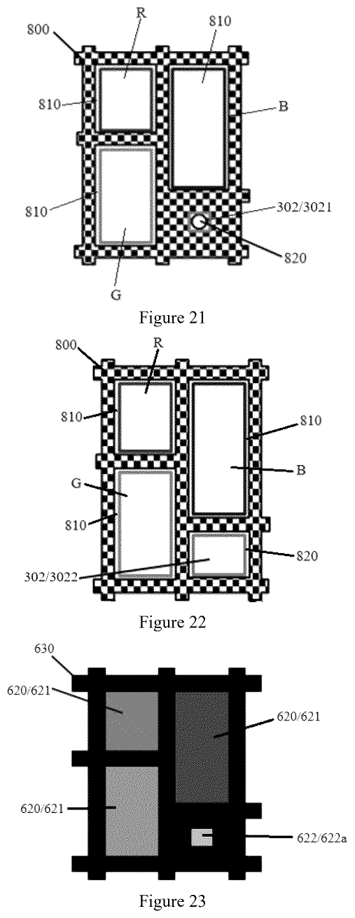

In some embodiments, as shown in FIGS. 20 and 21, the display panel further includes a second light shielding layer 800. The second light shielding layer 800 is located on the side of the first encapsulation layer 710 facing away from the substrate 100, and the second light shielding layer 800 includes a first light shielding opening 810 and a second light shielding opening 820. An orthographic projection of the first light shielding opening 810 on the substrate 100 at least partially overlaps an orthographic projection of the light-emitting structure 310 on the substrate 100, an orthographic projection of the second light shielding opening 820 on the substrate 100 at least partially overlaps the orthographic projection of the photoelectric sensing structure 320 on the substrate 100, and an area of the first light shielding opening 810 is greater than an area of the second light shielding opening 820.

In these embodiments, the display panel further include the second light shielding layer 800, the first light shielding opening 810 of the second light shielding layer 800 is disposed corresponding to the light-emitting structure 310 to improve the effect of the second light shielding layer 800 on the light emitted from the light-emitting structure 310. The second light shielding opening 820 is disposed corresponding to the photoelectric sensing structure 320 to improve the effect of the second light shielding layer 800 on the photoelectric sensing structure 320. Furthermore, by additionally providing the second light shielding layer 800, the second light shielding layer 800 can block light at other positions, and the light is incident to the photoelectric sensing structure 320 through the second light shielding opening 820, and the influence of stray light on the photoelectric sensing structure 320 can be alleviated.

In one embodiment, the second light shielding layer 800 doubles as a touch electrode TP. That is, a film layer where the touch electrode TP is located is provided with the first light shielding opening 810 and the second light shielding opening 820 as described above, and the functionality of the touch electrode TP can be enriched.

As shown in FIGS. 21 and 22, the first light shielding opening 810 is provided in a variety of shapes. For example, in some embodiments, the orthographic projection of the first light shielding opening 810 on the substrate 100 has a polygonal shape; and/or the orthographic projection of the first light shielding opening 810 on the substrate 100 is quadrilateral.

The second light shielding opening 820 is provided in a variety of shapes. In one embodiment, the orthographic projection of the second light shielding opening 820 on the substrate 100 has a circular, elliptical, or near-circular shape. In this way, when light passes through the second light shielding opening 820, pinhole imaging can be formed on the photoelectric sensing structure 320, thereby improving the sensing performance of the photoelectric sensing structure 320.

In one embodiment, the distribution area of an individual second light shielding opening 820 may be less than the distribution area of an individual photoelectric sensing structure 320. For example, the area of an individual second light shielding opening 820 is less than the distribution area of an individual second isolation opening 212 or an individual second opening 430, to facilitate the formation of pinhole imaging by light at the second light shielding opening 820.

In one embodiment, a material of the pixel defining portion 410 includes an inorganic material, to reduce the thickness of the pixel defining portion 410, thereby enabling thinning of the display panel.

In one embodiment, the orthographic projection of the first opening 420 on the substrate 100 is polygonal. For example, the orthographic projection of the first opening 420 on the substrate 100 is quadrilateral. In this way, the light-emitting sub-pixel 301 has a more regular shape and is easy to prepare.

In one embodiment, the orthographic projection of the second opening 430 on the substrate 100 may be circular, elliptical, or near-circular, and the shape of the second opening 430 is more adapted to the shape of the second light shielding opening 820.

In some embodiments, with continued reference to FIGS. 20 and 23, the display panel further includes filter portions 620. The filter portions 620 are located on the side of the first encapsulation layer 710 facing away from the substrate 100. The filter portions 620 include a first filter portion 621 and a second filter portion 622. An orthographic projection of the first filter portion 621 on the substrate 100 at least partially overlaps an orthographic projection of the light-emitting sub-pixel 301 on the substrate 100, and an orthographic projection of the second filter portion 622 on the substrate 100 at least partially overlaps an orthographic projection of the photosensitive sub-pixel 302 on the substrate 100. By providing the first filter portion 621, it is possible to filter the stray light emitted from the light-emitting structure 310, and to improve the display effect of the display panel. By providing the second filter portion 622, it is possible to filter the stray light incident on the photoelectric sensing structure 320, thereby improving the photoelectric sensing effect.

In one embodiment, referring to FIGS. 20 to 24 together, the second filter portion 622 includes a first subunit 622a and a second subunit 622b. The first subunit 622a and the second subunit 622b have at least partially different light transmission wavelength bands. A plurality of photosensitive sub-pixels 302 may be provided. An orthographic projection of the first subunit 622a on the substrate 100 at least partially overlaps an orthographic projection of the photosensitive structure of one of the plurality of photosensitive sub-pixels 302 on the substrate 100, and an orthographic projection of the second subunit 622b on the substrate 100 at least partially overlaps an orthographic projection of the photosensitive structure of the other of the plurality of photosensitive sub-pixels 302 on the substrate 100. That is, the first subunit 622a and the second subunit 622b are disposed corresponding to different photosensitive sub-pixels 302, and the first subunit 622a and the second subunit 622b are configured to filter different light, and light of different wavelengths can serve as light sources for the photosensitive sub-pixels 302.

In one embodiment, the photosensitive spectral characteristics of the plurality of photosensitive sub-pixels 302 are the same, and at least two of the photosensitive sub-pixels 302 are disposed corresponding to the first subunit 622a and the second subunit 622b, respectively. For example, when the photosensitive sub-pixels 302 can sense red light and green light, one of the at least two photosensitive sub-pixels 302 corresponds to the first subunit 622a and the other to the second subunit 622b, and part of the photosensitive sub-pixels 302 can sense red light, and the other part of the photosensitive sub-pixels 302 can sense green light.

A photosensitive sub-pixel 302 corresponding to the first subunit 622a means that the orthographic projection of the photoelectric sensing structure 320 of the photosensitive sub-pixel 302 on the substrate 100 at least partially overlaps the orthographic projection of the first subunit 622a on the substrate 100. A photosensitive sub-pixel 302 corresponding to the second subunit 622b means that the orthographic projection of the photoelectric sensing structure 320 of the photosensitive sub-pixel 302 on the substrate 100 at least partially overlaps the orthographic projection of the second subunit 622b on the substrate 100.

In one embodiment, as shown in FIGS. 20 to 24, the photosensitive sub-pixel 302 includes a first photosensitive unit 3021 and a second photosensitive unit 3022. The orthographic projection of the first subunit 622a on the substrate 100 at least partially overlaps an orthographic projection of the first photosensitive unit 3021 on the substrate 100, the orthographic projection of the second subunit 622b on the substrate 100 at least partially overlaps an orthographic projection of the second photosensitive unit 3022 on the substrate 100, the first photosensitive unit 3021 and the second photosensitive unit 3022 have different photosensitive wavelengths, the light transmission wavelength band of the first subunit 622a at least partially overlaps a photosensitive wavelength band of the first photosensitive unit 3021, and the light transmission wavelength band of the second subunit 622b at least partially overlaps a photosensitive wavelength band of the second photosensitive unit 3022.

For example, the first photosensitive unit 3021 is configured to sense a red wavelength band, and the first subunit 622a is configured to transmit the red wavelength band; and the second photosensitive unit 3022 is configured to sense a green wavelength band, and the second subunit 622b is configured to transmit the green wavelength band. By providing the first photosensitive unit 3021 and the second photosensitive unit 3022 with different photosensitive wavelength bands, the photosensitive wavelength band range of the photosensitive sub-pixel 302 can be expanded.

In one embodiment, the display panel further includes a first light shielding layer 630. The first light shielding layer 630 enclose filter openings in which the filter portions 620 are located. By providing the first light shielding layer 630, it is possible to provide a limit to a filter unit, and also to reduce the reflectivity of a film layer where a filter layer is located, thereby improving the display effect of the display panel.

In one embodiment, the first filter portion 621 corresponding to the light-emitting sub-pixel 301 is configured to transmit at least part of the emitted light from the light-emitting sub-pixel 301, to improve the effect of the first filter portion 621 on the light emitted from the light-emitting sub-pixel 301.

In one embodiment, the second filter portion 622 corresponding to the photosensitive sub-pixel 302 is configured to transmit at least part of the sensing light from the photosensitive sub-pixel 302, to improve the effect of the second filter portion 622 on the sensing light from the photosensitive sub-pixel 302.

In some embodiments, the first subunit 622a is configured to transmit green light, and the second subunit 622b is configured to transmit red light. The light-emitting structure 310 is typically configured to emit red, green, and blue light. The first subunit 622a is configured to transmit green light, and the second subunit 622b is configured to transmit red light, and the light-emitting structure 310 can serve as a light source for the photosensitive sub-pixel 302, thereby simplifying the structure of the display panel.

In one embodiment, the number m of first subunits 622a and the number n of second subunits 622b satisfy: m≥2n. In the display panel, the green light is more easily sensed, and when the number m of first subunit 622a and the number n of second subunit 622b satisfy the above relationship, the photosensitive effect can be improved.

In one embodiment, m≥5n, to further improve the photosensitive effect. In one embodiment, m≥10n, to further improve the photosensitive effect.

In one embodiment, when the first subunit 622a is configured to transmit green light and the second subunit 622b is configured to transmit red light, the photoelectric sensing structure 320 corresponding to the first subunit 622a is typically used to detect fingerprint recognition information, and the photoelectric sensing structure 320 corresponding to the second subunit 622b is used to detect biological health information such as blood sample concentration. When the number m of first subunits 622a and the number n of second subunits 622b satisfy the above relationship, it is ensured that there are enough photoelectric sensing structures 320 to receive optical images such as fingerprints, and high resolution images can be acquired. As a result, high-precision biometric recognition is possible. In addition, the photoelectric sensing structure 320, which is basically used to detect blood oxygen concentration (SpO2), can maintain the functionality of a bio-health sensor without the need for high resolution images.

In one embodiment, the area of the orthographic projection of the first subunit 622a on the substrate 100 is less than or equal to the area of the orthographic projection of the second subunit 622b on the substrate 100. In this way, the distribution area of an individual first subunit 622a is more adapted to the distribution area of the green light-emitting sub-pixel 301, and the distribution area of an individual second subunit 622b is more adapted to the distribution area of the red light-emitting sub-pixel 301.

In one embodiment, the light-emitting sub-pixels 301 include a red sub-pixel R, a green sub-pixel G and a blue sub-pixel B. The distribution area of an individual red sub-pixel R is greater than the distribution area of an individual green sub-pixel G, and the distribution area of the blue sub-pixel B is greater than the distribution area of an individual red sub-pixel R.

In one embodiment, the first photosensitive unit 3021 is configured to sense green light, and the second photosensitive unit 3022 is configured to sense red light. The distribution area of an individual first photosensitive unit 3021 is smaller than the distribution area of an individual second photosensitive unit 3022, and the distribution area of the photosensitive sub-pixel 302 is more adapted to the distribution area of the light-emitting sub-pixel 301.

In some embodiments, the first subunit 622a is configured to transmit red light, and the second subunit 622b is configured to transmit infrared light. In one embodiment, infrared light has a wavelength of 700 nm to 1000 nm. In one embodiment, the first photosensitive unit 3021 is configured to sense red light, and the second photosensitive unit 3022 is configured to sense infrared light. In one embodiment, each of the first photosensitive unit 3021 and the second photosensitive unit 3022 may be capable of sensing red and infrared light, and the photosensitive sub-pixel 302 can sense not only red light, but also infrared light to meet different photosensitive requirements.

In one embodiment, the number p of first subunits 622a and the number q of second subunits 622b satisfy: p≤2q, to meet actual requirements. In one embodiment, p≤5q. In one embodiment, p≤10q.

In one embodiment, the area of the orthographic projection of the first subunit 622a on the substrate 100 is less than or equal to the area of the orthographic projection of the second subunit 622b on the substrate 100.

In some embodiments, as shown in FIGS. 20 to 26, the display panel further includes a light adjustment layer 530. The light adjustment layer 530 is located on the side of the first encapsulation layer 710 facing away from the substrate 100, and the light adjustment layer 530 includes a first adjustment layer. The first adjustment layer includes a first adjustment protrusion 531 and a second adjustment protrusion 532. An orthographic projection of the first adjustment protrusion 531 on the substrate 100 at least partially overlaps an orthographic projection of the light-emitting sub-pixel 301 on the substrate 100, and an orthographic projection of the second adjustment protrusion 532 on the substrate 100 at least partially overlaps the orthographic projection of the photoelectric sensing structure 320 on the substrate 100.

In these embodiments, by providing the light adjustment layer 530, the first adjustment protrusion 531 of the light adjustment layer 530 corresponding to the light-emitting sub-pixel 301 can improve the light-emitting effect of the light-emitting sub-pixel 301, and the second adjustment protrusion 532 of the light adjustment layer 530 corresponding to the photosensitive sub-pixel 302 can improve the sensing effect of the photosensitive sub-pixel 302.

In one embodiment, orthographic projections of a plurality of first adjustment protrusions 531 on the substrate 100 at least partially overlap the orthographic projection of the same light-emitting sub-pixel 301 on the substrate 100. The same light-emitting sub-pixel 301 being disposed corresponding to a plurality of first adjustment protrusions 531 can further improve the light-emitting effect.

In one embodiment, the second adjustment protrusion 532 is disposed corresponding to the photoelectric sensing structure 320 on a one-to-one basis, and a center of the orthographic projection of the adjustment protrusion on the substrate 100 overlaps a center of the orthographic projection of the photoelectric sensing structure 320 on the substrate 100. The second adjustment protrusion 532 can provide a light converging effect, and the center of the second adjustment protrusion 532 is disposed corresponding to the center of the photoelectric sensing structure 320, and more light can converge and be incident on the center of the photoelectric sensing structure 320, improving the photoelectric sensing effect.

In one embodiment, the display panel further includes a light protection layer 540. The light protection layer 540 is disposed on a side of the light adjustment layer 530 facing away from the substrate 100. A refractive index of the light protection layer 540 is less than a refractive index of the light adjustment layer 530. For the light-emitting sub-pixel 301, when the emitted light is incident on a contact interface between the light protection layer 540 and the light adjustment layer 530, since the refractive index of the light protection layer 540 is less than the refractive index of the light adjustment layer 530, the light is deflected toward the center of the light-emitting sub-pixel 301, and the angle of the light emitted at a large angle becomes smaller after passing through the contact interface, and more light can be emitted in the direction of the normal viewing angle, thereby improving the display effect of the display panel at the normal viewing angle. For the photosensitive sub-pixel 302, the incident light converges when passing through the contact interface, causing more light to be incident on the photosensitive sub-pixel 302.

In one embodiment, the refractive index of the light adjustment layer 530 is greater than 1.5. For example, the refractive index of the light adjustment layer 530 is greater than 1.55. In one embodiment, the refractive index of the light protection layer 540 is less than 1.5. For example, the refractive index of the light protection layer 540 is less than 1.4.

In one embodiment, when the display panel includes the second light shielding layer 800 and the second light shielding opening 820 described above, the center of the orthographic projection of the second adjustment protrusion 532 on the substrate 100 overlaps the center of the orthographic projection of the second light shielding opening 820 on the substrate 100.

An embodiment of the first aspect of the present application provides a display panel. Referring to FIGS. 1 to 29 together, the display panel includes: a substrate 100; a light-emitting sub-pixel 301 disposed on one side of the substrate 100, the light-emitting sub-pixel 301 including a light-emitting structure 310; and a photosensitive sub-pixel 302 disposed on one side of the substrate 100, the photosensitive sub-pixel 302 including a photoelectric sensing structure 320, a material of the photoelectric sensing structure 320 including a donor material 321 and an acceptor material 322. The donor material 321 and the acceptor material 322 interact with each other to achieve photoelectric sensing, and the light energy can be converted into electrical energy within the photoelectric sensing structure 320. A material of the light-emitting structure 310 includes an organic light-emitting diode material, and electrical energy can be converted into light energy within the light-emitting structure 310.

In one embodiment, the material of the light-emitting structure 310 includes a host material and a dopant material. The light-emitting structure 310 is formed by co-evaporation of the dopant material and the host material under vacuum. The photoelectric sensing structure 320 is formed by co-evaporation of the donor material 321 and the acceptor material 322 under vacuum.

In one embodiment, the light-emitting spectral characteristics of the light-emitting structure 310 at least partially overlap the photosensitive spectral characteristics of the photoelectric sensing structure 320. That is, the photoelectric sensing structure 320 can sense at least part of light emitted from the light-emitting structure 310. For example, when the light-emitting structure 310 is configured to emit red light, green light and blue light, the photoelectric sensing structure 320 may be configured to sense at least one of the red light, the green light and the blue light. In this way, the light-emitting structure 310 may serve as a light source for the photoelectric sensing structure 320, and it is possible to simplify the structure of the display panel without the need for providing a separate light source for the photoelectric sensing structure 320.

In some embodiments, the light-emitting structure 310 includes a host material and a dopant material, a doping ratio of the dopant material to the host material ranging from 0.01% to 10%. That is, the ratio of the volume and/or weight of the dopant material to the volume and/or weight of the host material ranges from 0.01% to 10%, to ensure the performance of the light-emitting structure 310. For example, the doping ratio of the dopant material to the host material is 0.01%, 0.05%, 0.9%, 5.8%, 9.2%, and 10%.

In one embodiment, a doping ratio of the dopant material to the host material ranges from 0.1% to 1%, to improve the performance of the light-emitting structure 310. For example, the doping ratio of the dopant material to the host material is 0.1%, 0.5%, 0.65%, 0.9%, and 1%.

In some embodiments, a ratio of the donor material 321 to the acceptor material 322 ranges from 20/1 to 1/20, to ensure the performance of the photoelectric sensing structure 320. For example, the ratio of the donor material 321 to the acceptor material 322 is 20/1, 15/1, 18/20, 7/18, and 1/20.

In one embodiment, the doping ratio of the donor material 321 to the acceptor material 322 ranges from 5/1 to 1/5, to improve the performance of the photoelectric sensing structure 320. For example, the ratio of the donor material 321 to the acceptor material 322 is 5/1, 4/1, 3/2, 2/3, and 1/5.

In one embodiment, a LUMO energy level of the donor material 321 is shallower than a LUMO energy level of the acceptor material 322, i.e., an electron energy level of the donor material 321 is higher than an electron energy level of the acceptor material 322, and/or a HOMO energy level of the donor material 321 is shallower than a HOMO energy level of the acceptor material 322.

In one embodiment, the acceptor material 322 includes fullerene or a fullerene derivative. The fullerene includes C60 or C70.

In one embodiment, the photoelectric sensing structure 320 includes a plurality of film layers, and a donor layer is formed on the side of the first electrode 510 and an acceptor layer is formed on the side of the second electrode 520 with respect to a co-deposited layer of the donor material 321 and the acceptor material, and the donor layer and the acceptor layer are in contact with the co-deposited layer.

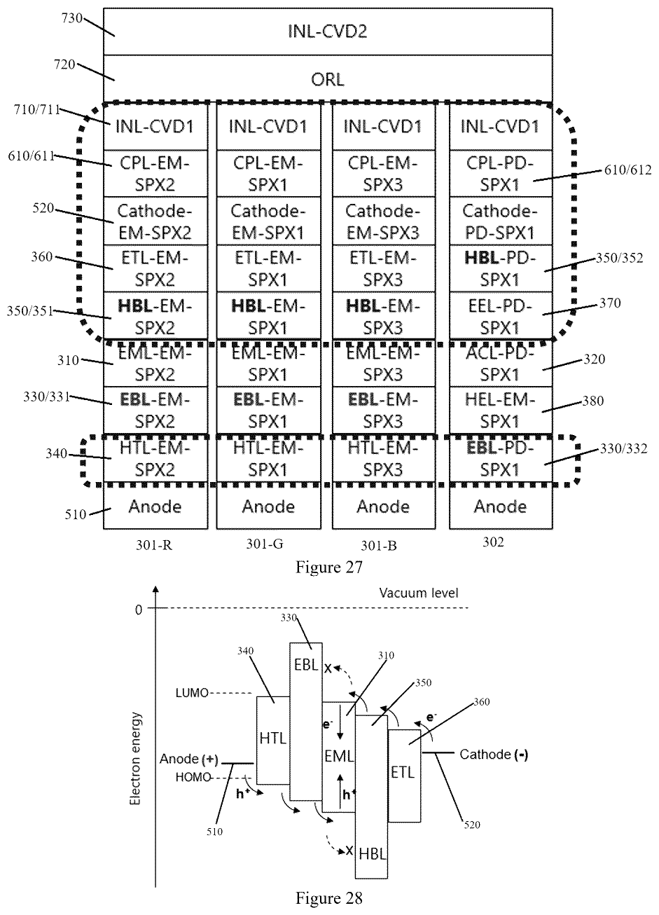

In one embodiment, as shown in FIGS. 27 to 29, the display panel further includes an electron blocking layer 330 disposed on a side of the light-emitting structure 310 and the photoelectric sensing structure 320 facing the substrate 100. The HOMO energy level of the donor material 321 is lower than or equal to a HOMO energy level of the electron blocking layer 330.

In the display panel according to the embodiment of the present application, the display panel includes the substrate 100, the light-emitting sub-pixel 301, the photosensitive sub-pixel 302, and the electron blocking layer 330. The light-emitting structure 310 of the light-emitting sub-pixel 301 is configured to achieve the light-emitting display of the display panel, and the photoelectric sensing structure 320 of the photosensitive sub-pixel 302 is configured to achieve the photoelectric sensing function of the display panel. The electron blocking layer 330 is disposed on the side of the light-emitting structure 310 and the photoelectric sensing structure 320 facing the substrate 100, and the HOMO energy level of the donor material 321 of the photoelectric sensing structure 320 is lower than or equal to the HOMO energy level of the electron blocking layer 330, and it is possible to reduce the energy difference between the electron blocking layer 330 and the donor material 321, and carriers are better transported between the electron blocking layer 330 and the donor material 321, reducing the dark current density, increasing the current intensity in the photoelectric sensing structure 320, improving the photosensitive effect of the photosensitive sub-pixel 302, and thus improving the performance of the photo detector in the display panel.

In one embodiment, the material of the light-emitting structure 310 includes an organic light-emitting diode material.

The HOMO energy level of the donor material 321 being lower than the HOMO energy level of the electron blocking layer 330 means that the HOMO energy level of the donor material 321 is shallower relative to the HOMO energy level of the electron blocking layer 330, and the HOMO energy level of the donor material 321 is shallower than the HOMO energy level of the electron blocking layer 330.

In one embodiment, a LUMO energy level of the light-emitting structure 310 may be lower than or equal to a LUMO energy level of the acceptor material 322.

In one embodiment, the small molecule material of the photoelectric sensing structure 320 may include: at least one of

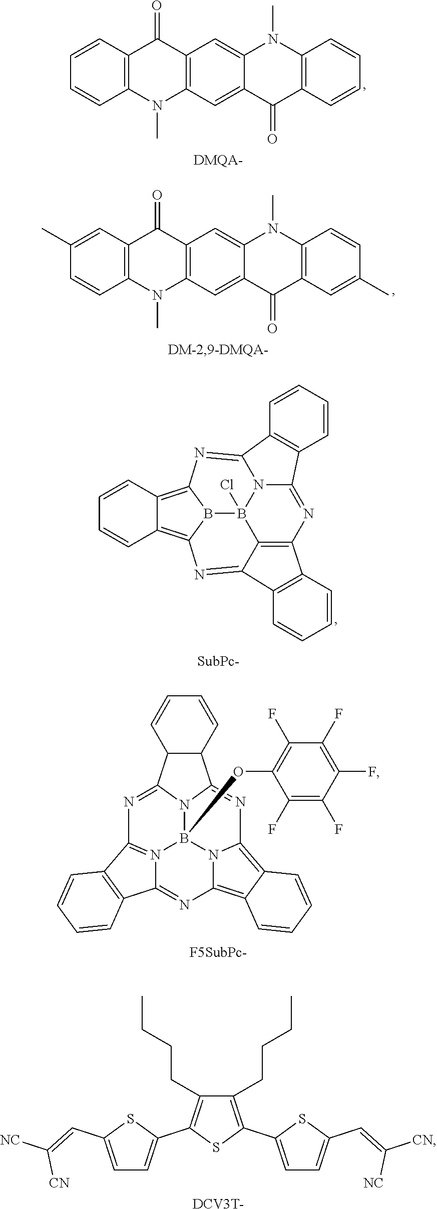

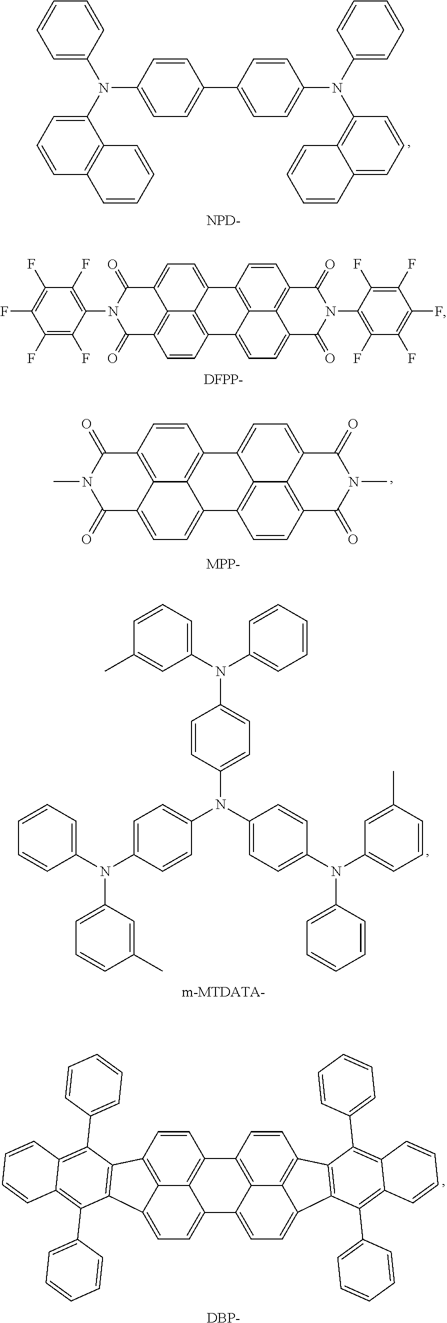

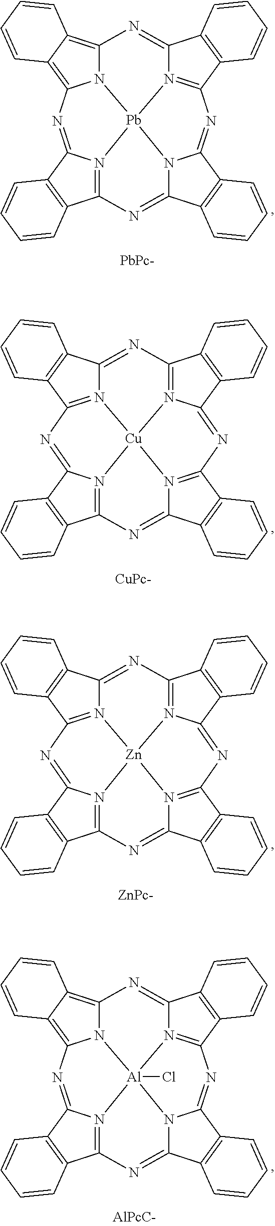

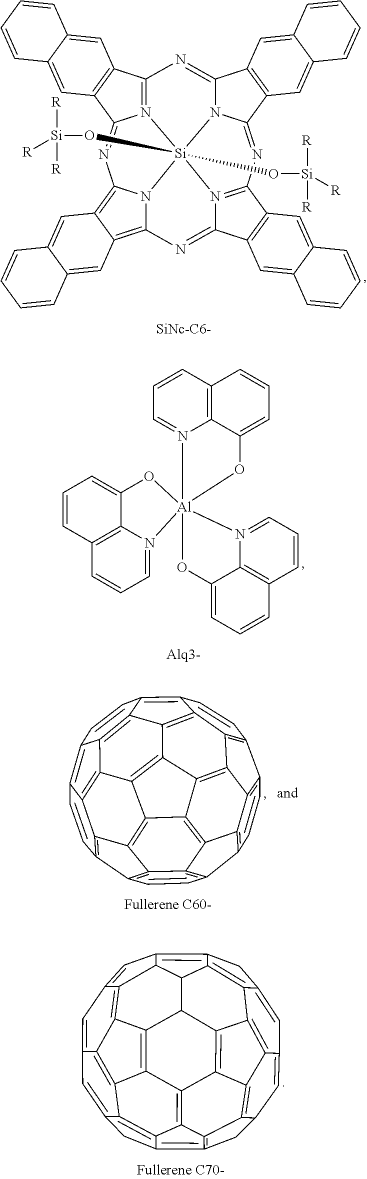

In one embodiment, the organic material in the photoelectric sensing structure 320 may include at least one of

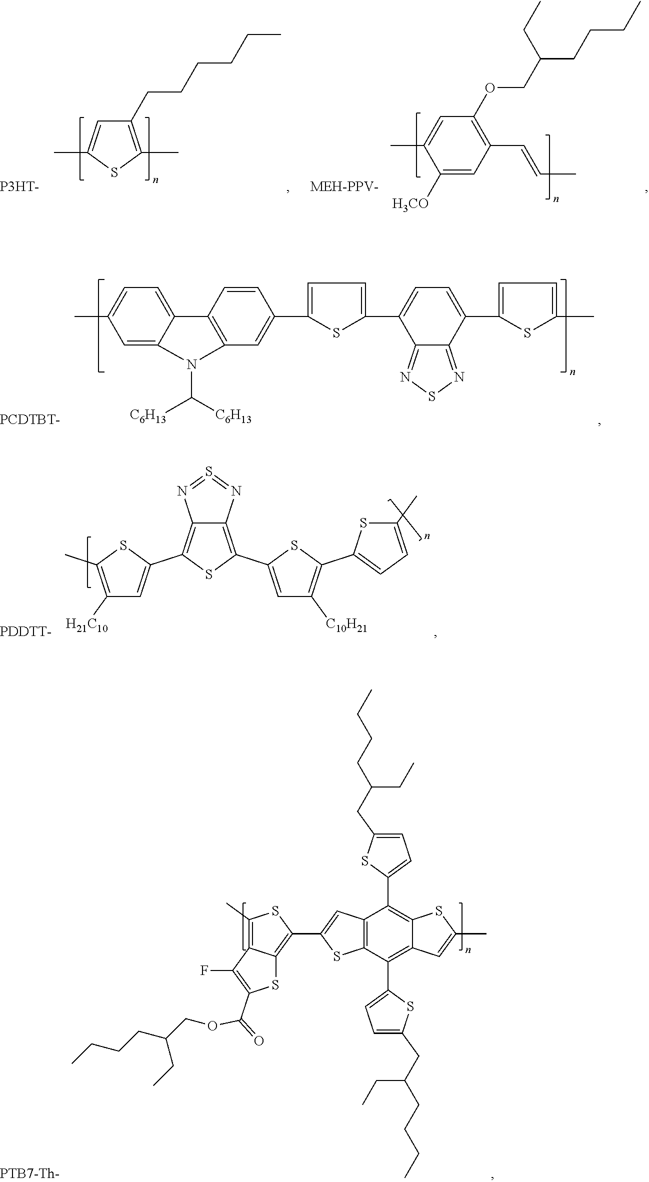

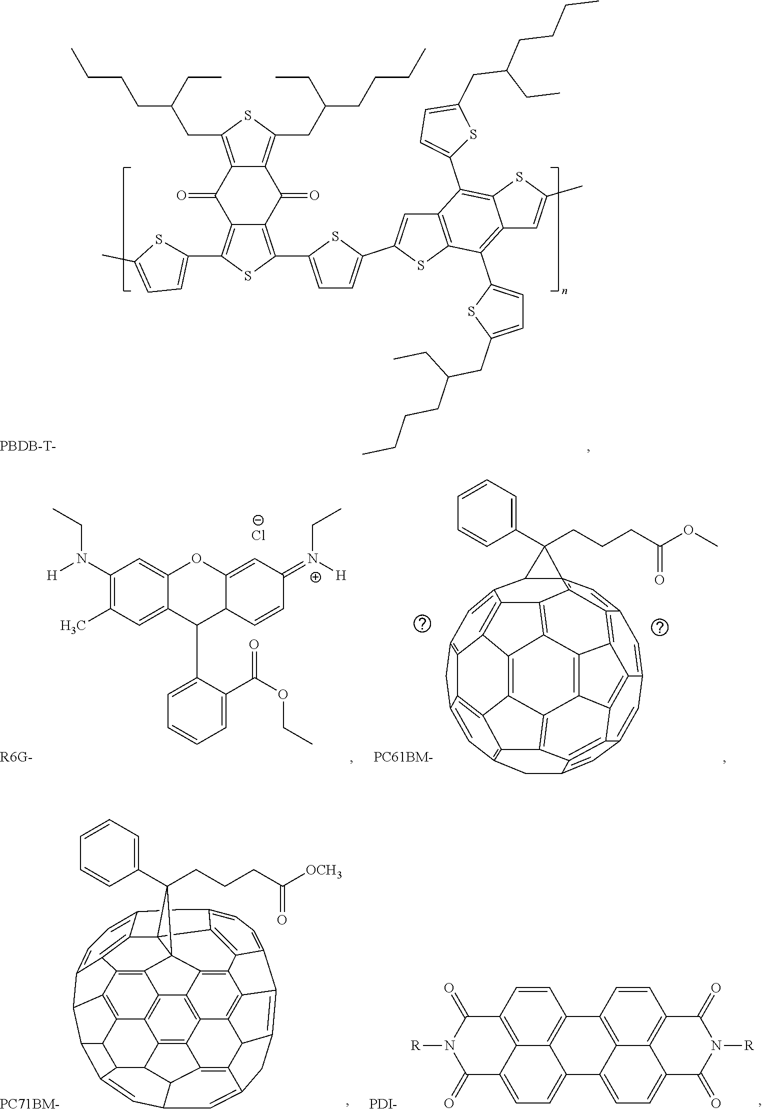

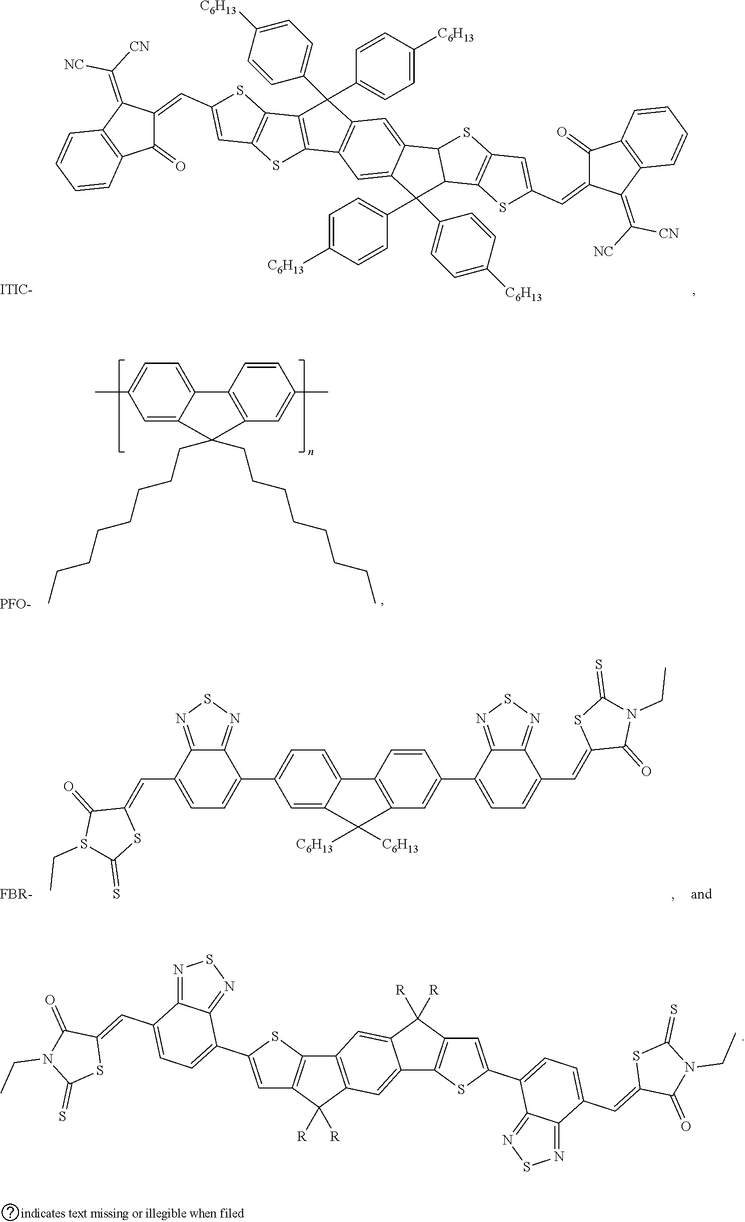

The material of the electron blocking layer 330 may include at least one of TAPC—

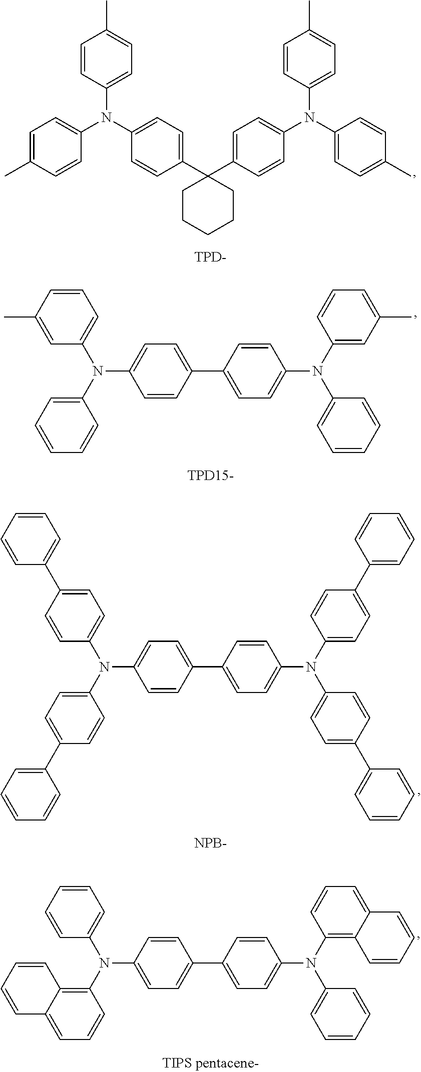

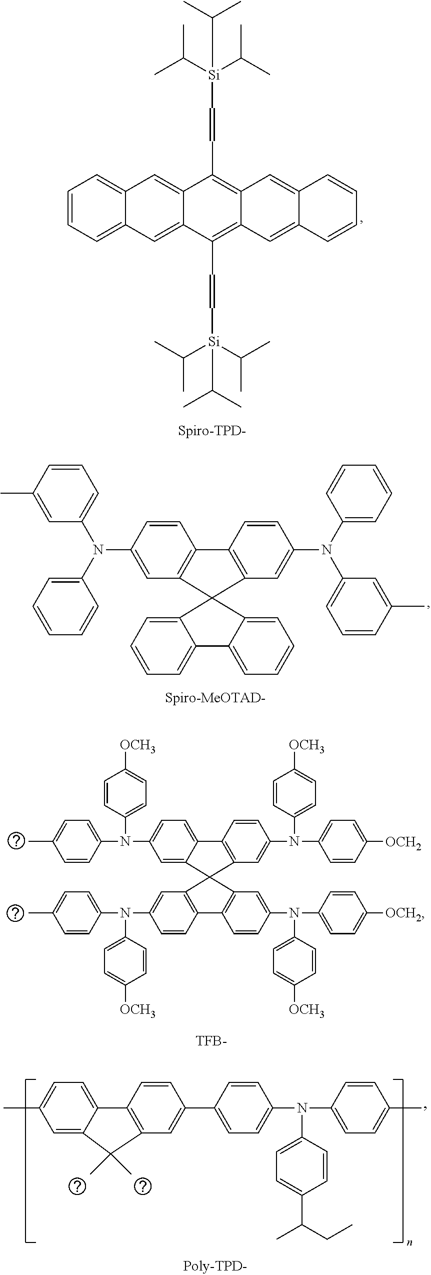

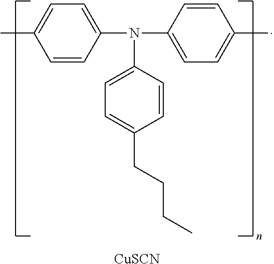

NiOx, V₂O₅, MoO₃, SiOxNy, and

The material of the hole blocking layer 350 includes at least one of BCP—

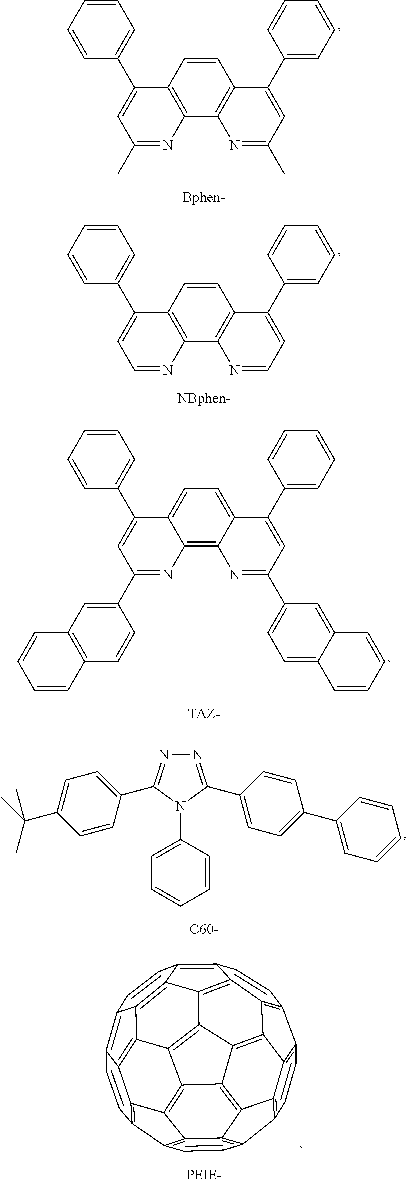

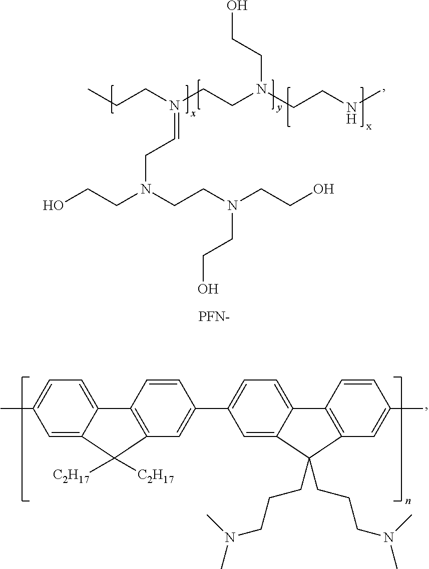

TiO₂, SnO₂, and Cs₂CO₃.

In one embodiment, the donor material 321 is located on a side of the acceptor material 322 facing the electron blocking layer 330, and holes in the donor material 321 can move more quickly to the electron blocking layer 330.

In some embodiments, as shown in FIGS. 27 to 29, the HOMO energy level of the electron blocking layer 330 is higher than or equal to the HOMO energy level of the light-emitting structure 310, and the electron blocking layer 330 can better block electrons that overflow from the light-emitting structure 310.

In one embodiment, the display panel further includes first electrodes 510 and second electrodes 520. Each of the light-emitting structure 310 and the photoelectric sensing structure 320 is provided with the first electrode 510 on a side facing the substrate 100, each of the light-emitting structure 310 and the photoelectric sensing structure 320 is provided with the second electrode 520 on a side facing away from the substrate 100, and the electron blocking layer 330 is located on a side of the first electrodes 510 facing away from the substrate 100.

In these embodiments, the first electrodes 510 and the second electrodes 520 may be configured to drive the light-emitting structure 310 to emit light, and an electrical signal generated by the photoelectric sensing structure 320 may be transmitted to the outside through the first electrodes 510 and the second electrodes 520. The electron blocking layer 330 is located between the first electrode 510 and the photoelectric sensing structure 320 and the light-emitting structure 310, and the electron blocking layer 330 can block the flow of electrons overflowing from the light-emitting structure 310 to the first electrode 510 and enable more efficient transport of holes between the first electrode 510 and the photoelectric sensing structure 320.

In one embodiment, the light-emitting sub-pixel 301 further includes a hole transport layer 340 located on the side of the light-emitting structure 310 facing the substrate 100. The electron blocking layer 330 includes a first section 331 and a second section 332. The first section 331 is located between the hole transport layer 340 and the light-emitting structure 310, and the second section 332 is located between the first electrode 510 and the photoelectric sensing structure 320.

In these embodiments, the first section 331 of the electron blocking layer 330 is located between the hole transport layer 340 of the light-emitting sub-pixel 301 and the light-emitting structure 310, to block the transport of current overflowing from the light-emitting structure 310 to the hole transport layer 340. The second section 332 of the electron blocking layer 330 is located between the first electrode 510 and the photoelectric sensing structure 320, and holes are better transported from the photoelectric sensing structure 320 to the first electrode 510.

In one embodiment, a LUMO energy level of the hole transport layer 340 is lower than a LUMO energy level of the electron blocking layer 330. For example, the LUMO energy level of the hole transport layer 340 is lower than a LUMO energy level of the first section 331.

In one embodiment, a HOMO (Highest Occupied Molecular Orbital) energy level of the hole transport layer 340 is higher than the HOMO energy level of the electron blocking layer 330, thereby enabling better transport of holes from the hole transport layer 340 to the electron blocking layer 330.

In one embodiment, the second section 332 may be in contact connection with the first electrode 510, i.e., no other film layer may be provided between the second section 332 and the first electrode 510, to alleviate the problem of the other film layer affecting the transport of holes between the second section 332 and the first electrode 510.

In one embodiment, the LUMO energy level of the electron blocking layer 330 is higher than the LUMO energy level of the donor material 321. In one embodiment, the HOMO energy level of the electron blocking layer 330 is higher than the HOMO energy level of the donor material 321, enabling better transport of holes from the donor material 321 to the electron blocking layer 330.

In some embodiments, as shown in FIGS. 27 to 29, the display panel further includes a hole blocking layer 350. The hole blocking layer 350 is disposed on the side of the light-emitting structure 310 and the photoelectric sensing structure 320 facing away from the substrate 100, and a LUMO energy level of the hole blocking layer 350 is higher than or equal to the LUMO energy level of the acceptor material 322.

In these embodiments, the hole blocking layer 350 is disposed on the side of the photoelectric sensing structure 320 facing away from the substrate 100, and the LUMO energy level of the hole blocking layer 350 is higher than or equal to the LUMO energy level of the acceptor material 322, making it difficult for electrons to be transported from the photoelectric sensing structure 320 to the hole blocking layer 350.

In one embodiment, the LUMO energy level of the hole blocking layer 350 is lower than or equal to the LUMO energy level of the donor material 321, making it difficult for electrons to be transported from the photoelectric sensing structure 320 to the hole blocking layer 350.

In one embodiment, the second electrode 520 is located on a side of the hole blocking layer 350 facing away from the photoelectric sensing structure 320, and the LUMO energy level of the hole blocking layer 350 is lower than the LUMO energy level of the acceptor material 322. In one embodiment, the HOMO energy level of the hole blocking layer 350 is lower than the HOMO energy level of the acceptor material 322, enabling better transport of electrons from the layer of the acceptor material 322 to the hole blocking layer 350 and, in turn, to the second electrode 520.

In some embodiments, the light-emitting sub-pixel 301 further includes an electron transport layer 360 located on the side of the light-emitting structure 310 facing away from the substrate 100. The hole blocking layer 350 includes a third section 351 and a fourth section 352. The third section 351 is located between the electron transport layer 360 and the light-emitting structure 310, and the fourth section 352 is located between the second electrode 520 and the photoelectric sensing structure 320.

In these embodiments, the third section 351 of the hole blocking layer 350 is located between the electron transport layer 360 and the light-emitting structure 310, and can block the overflow of holes from the light-emitting structure 310 to the electron transport layer 360, and the fourth section 352 of the hole blocking layer 350 is located between the second electrode 520 and the photoelectric sensing structure 320, enabling better transport of electrons between the photoelectric sensing structure 320 and the second electrode 520.

In one embodiment, the fourth section 352 is in contact connection with the second electrode 520, enabling better transport of electrons between the hole blocking layer 350 and the second electrode 520.

In one embodiment, a LUMO energy level of the electron transport layer 360 is lower than the LUMO energy level of the hole blocking layer 350, enabling better movement of electrons in the light-emitting sub-pixel 301 from the electron transport layer 360 to the hole blocking layer 350.

In one embodiment, a HOMO energy level of the electron transport layer 360 is higher than the HOMO energy level of the hole blocking layer 350, enabling better movement of electrons in the light-emitting sub-pixel 301 from the electron transport layer 360 to the hole blocking layer 350.

In some embodiments, the photosensitive sub-pixel 302 further includes an electron extraction layer 370. The electron extraction layer 370 is located between the photoelectric sensing structure 320 and the hole blocking layer 350. By providing the electron extraction layer 370, the electron extraction efficiency can be improved and the photosensitive effect can be improved.

In one embodiment, a LUMO energy level of the electron extraction layer 370 is higher than the LUMO energy level of the hole blocking layer 350, enabling better movement of electrons from the electron extraction layer 370 to the hole blocking layer 350.

In one embodiment, a HOMO energy level of the electron extraction layer 370 is higher than the HOMO energy level of the hole blocking layer 350, making it difficult for holes to move from the electron extraction layer 370 to the hole blocking layer 350.

In one embodiment, the LUMO energy level of the electron extraction layer 370 is lower than the LUMO energy level of the acceptor material 322, enabling better movement of electrons from the acceptor material 322 to the electron extraction layer 370.

In one embodiment, the HOMO energy level of the electron extraction layer 370 is lower than the HOMO energy level of the acceptor material 322, making it difficult for holes to move from the acceptor material 322 to the electron extraction layer 370.

In some embodiments, the photosensitive sub-pixel 302 further includes a hole extraction layer 380. The hole extraction layer 380 is located between the electron blocking layer 330 and the photoelectric sensing structure 320. By providing the electron extraction layer 370, the hole extraction efficiency can be improved and the photosensitive effect can be improved.

In one embodiment, the LUMO energy level of the electron blocking layer 330 is higher than a LUMO energy level of the hole extraction layer 380. In one embodiment, the HOMO energy level of the electron blocking layer 330 is higher than a HOMO energy level of the hole extraction layer 380, enabling better movement of holes from the electron blocking layer 330 to the hole extraction layer 380.

In one embodiment, the LUMO energy level of the hole extraction layer 380 is lower than the LUMO energy level of the donor material 321. In one embodiment, the HOMO energy level of the hole extraction layer 380 is higher than the HOMO energy level of the donor material 321, enabling better movement of holes from the donor material 321 to the hole extraction layer 380.

In some embodiments, the acceptor material 322 includes fullerene or a fullerene derivative, to improve the performance of the photoelectric sensing structure 320.

As shown in FIGS. 1 to 29, an embodiment of the first aspect of the present application further provides a display panel, including: a substrate 100; a light-emitting functional layer 300 disposed on one side of the substrate 100, the light-emitting functional layer 300 including a light-emitting structure 310 and a photoelectric sensing structure 320, a material of the photoelectric sensing structure 320 including a donor material 321 and an acceptor material 322; and a hole blocking layer 350 disposed on a side of the light-emitting functional layer 300 facing the substrate 100, a HOMO energy level of the hole blocking layer 350 being lower than or equal to a HOMOenergy level of the acceptor material 322, and/or a LUMO energy level of the hole blocking layer 350 being lower than or equal to a LUMO energy level of the acceptor material 322.

In the embodiment of the present application, the display panel includes the substrate 100, the light-emitting functional layer 300, and the hole blocking layer 350, where the light-emitting functional layer 300 includes the light-emitting structure 310 and the photoelectric sensing structure 320, and the light-emitting structure 310 and the photoelectric sensing structure 320 can be prepared in the same process step, and the preparation process of the display panel can be simplified. The HOMO energy level of the hole blocking layer 350 is lower than or equal to the energy level of the acceptor material 322, and/or the LUMO energy level of the hole blocking layer 350 is lower than or equal to the energy level of the acceptor material 322, enabling better transport of electrons from the acceptor material 322 to the hole blocking layer 350, and the sensing effect of the photoelectric sensing structure 320 can be improved, thereby improving the performance of the photo detector in the display panel.

The display panel of the embodiment of the present application and the display panel of any of the above embodiments may be cross-referenced.

In some embodiments, the material of the photoelectric sensing structure 320 includes a donor material 321 and an acceptor material 322, the donor material 321 and the acceptor material 322 interacting with each other to achieve photoelectric sensing. In one embodiment, the donor material 321 is located on a side of the acceptor material 322 facing the first electrode 510.

In one embodiment, as above, as shown in FIGS. 27 to 29, the display panel further includes an electron blocking layer 330. The electron blocking layer 330 is disposed on a side of the photoelectric sensing structure 320 facing away from the substrate 100. The HOMO energy level of the donor material 321 is lower than or equal to a HOMO energy level of the electron blocking layer 330. The configuration of the electron blocking layer 330 is as described above and will not be described in detail herein.

In one embodiment, the electron blocking layer 330 is located in the second isolation opening 212 and the electron blocking layer 330 can be disposed corresponding to the photoelectric sensing structure 320.

In one embodiment, as above, the light-emitting sub-pixel 301 of the display panel further includes a hole transport layer 340 located on the side of the light-emitting structure 310 facing the substrate 100. The electron blocking layer 330 includes a first section 331 and a second section 332. The first section 331 is located between the hole transport layer 340 and the light-emitting structure 310, and the second section 332 is located between the first electrode 510 and the photoelectric sensing structure 320. The configuration of the hole transport layer 340 is as described above and will not be described in detail herein.

In one embodiment, the materials of the light-emitting structure 310 and the photoelectric sensing structure 320 are configured as above and will not be described in detail herein.

In some embodiments, the display panel further includes a hole blocking layer 350 disposed on the side of the photoelectric sensing structure 320 facing the substrate 100, and a LUMO energy level of the hole blocking layer 350 is higher than or equal to the LUMO energy level of the acceptor material 322. The configuration of the hole blocking layer 350 is as described above and will not be described in detail herein.

In some embodiments, the photosensitive sub-pixel 302 further includes an electron extraction layer 370. The electron extraction layer 370 is located between the photoelectric sensing structure 320 and the hole blocking layer 350. The configuration of the electron extraction layer 370 is as described above and will not be described in detail herein.

In some embodiments, the photosensitive sub-pixel 302 further includes a hole extraction layer 380. The hole extraction layer 380 is located between the electron blocking layer 330 and the photoelectric sensing structure 320. The configuration of the hole extraction layer 380 is as described above and will not be described in detail herein.

As shown in FIGS. 1 to 31, an embodiment of a second aspect of the present application further provides a display module 10, including the display panel according to any one of the above embodiments of the first aspect. Since the display module 10 according to the embodiment of the second aspect of the present application includes the display panel of any one of the above embodiments of the first aspect, the display module 10 according to the embodiment of the second aspect of the present application has the beneficial effects of the display panel of any one of the above embodiments of the first aspect. No detailed description will be given here.

The display module 10 in the embodiments of the present application includes, but is not limited to, devices having a display function, such as a mobile phone, a personal digital assistant (PDA), a tablet computer, an e-book reader, a television, an access control system, a smart fixed-line telephone, or a console.

In one embodiment, as shown in FIGS. 30 to 33, the photosensitive sub-pixel 302 may be used for fingerprint recognition. When the light-emitting sub-pixel 301 serves as a light source for the photosensitive sub-pixel 302, the light emitted by the light-emitting sub-pixel 301 irradiates a surface of the display panel and reaches the user's finger, and is then reflected to the photosensitive sub-pixel 302. The photosensitive sub-pixel 302 detects the light reflected by the finger, thereby enabling fingerprint recognition. The photosensitive sub-pixel 302 may also be configured to obtain biological information such as palm vein, pulse, blood pressure, and blood oxygen concentration.

In some embodiments, the display module 10 further includes an encapsulation layer and a second light shielding layer 800 as described above. The configurations of the encapsulation layer and the second light shielding layer 800 are as described above and will not be described in detail herein. For example, the encapsulation layer is located on the side of the light-emitting sub-pixel 301 and the photosensitive sub-pixel 302 facing away from the substrate 100. The second light shielding layer 800 is located on the side of the encapsulation layer facing away from the substrate 100, and the second light shielding layer includes a first light shielding opening 810 and a second light shielding opening 820. An orthographic projection of the first light shielding opening 810 on the substrate 100 at least partially overlaps an orthographic projection of the light-emitting structure 310 on the substrate 100, an orthographic projection of the second light shielding opening 820 on the substrate 100 at least partially overlaps the orthographic projection of the photoelectric sensing structure 320 on the substrate 100, and an area of the first light shielding opening 810 is greater than an area of the second light shielding opening 820.

The display module 10 further includes a light adjustment layer 530 and a light protection layer 540 as described above.

An embodiment of the second aspect of the present application further provides a display module 10, including: a substrate 100; a pixel unit 30a disposed on the substrate 100 and including a light-emitting sub-pixel 301 and a photosensitive sub-pixel 302; and filter portions 620 disposed on a side of the pixel unit 30a facing away from the substrate 100. The filter portions 620 include a first filter portion 621 and a second filter portion 622. An orthographic projection of the first filter portion 621 on the substrate 100 at least partially overlaps an orthographic projection of the light-emitting sub-pixel 301 on the substrate 100, and an orthographic projection of the second filter portion 622 on the substrate 100 at least partially overlaps an orthographic projection of the photosensitive sub-pixel 302 on the substrate 100. The second filter portion 622 includes a first subunit 622a and a second subunit 622b, the first subunit 622a and the second subunit 622b having at least partially different light transmission wavelength bands.

In the display panel according to the embodiment of the present application, the display panel includes the substrate 100, the pixel unit 30a, and the filter portions 620, where the light-emitting sub-pixel 301 of the pixel unit 30a is configured to achieve the light-emitting display of the display panel, and the photosensitive sub-pixel 302 is configured to achieve the sensing function of the display panel. By providing the first filter portion 621, it is possible to filter the stray light emitted from the light-emitting structure 310, and to improve the display effect of the display panel. By providing the second filter portion 622, it is possible to filter the stray light incident on the photoelectric sensing structure 320, thereby improving the photoelectric sensing effect. The first subunit 622a and the second subunit 622b may be disposed corresponding to different photosensitive sub-pixels 302, and the first subunit 622a and the second subunit 622b are configured to filter different light, and light of different wavelengths can serve as light sources for the photosensitive sub-pixels 302.

The display module 10 of the embodiment of the present application and the display module 10 of the above embodiments may be cross-referenced to each other. The display module 10 of the embodiment of the present application may include a display panel of any of the above embodiments.

For example, the configuration of the photosensitive sub-pixel 302 in the display module 10 is as described above. The photosensitive spectral characteristics of the plurality of photosensitive sub-pixels 302 are the same, and at least two of the photosensitive sub-pixels 302 are disposed corresponding to the first subunit 622a and the second subunit 622b, respectively.

For example, the photosensitive sub-pixel 302 includes the first photosensitive unit 3021 and the second photosensitive unit 3022 described above. The configurations of the first photosensitive unit 3021 and the second photosensitive unit 3022 are as described above and will not be described in detail herein.

In one embodiment, when the first subunit 622a is configured to transmit green light and the second subunit 622b is configured to transmit red light, the settings of the number m of first subunits 622a and the number n of second subunits 622b are as described above and will not be described in detail herein.

In one embodiment, when the first subunit 622a is configured to transmit red light and the second subunit 622b is configured to transmit infrared light, the setting of the number p of first subunits 622a and the number q of second subunits 622b satisfying p≤ 2q is as described above and will not be described in detail herein.

In any of the above embodiments, the light-emitting structure 310 of the light-emitting sub-pixel 301 is a structure for converting an electrical signal into an optical signal to achieve the light-emitting display of the display panel. In one embodiment, the photoelectric sensing structure 320 of the photosensitive sub-pixel 302 is a structure for converting an optical signal into an electrical signal to achieve the photoelectric detection function of the display panel. In one embodiment, the photoelectric sensing unit may be the OPD device mentioned above.

In one embodiment, one of the first electrode 510 and the second electrode 520 is an anode, and the other is a cathode. An embodiment of the present application is exemplified by using the first electrode 510 as the anode and the second electrode 520 as the cathode. A material of the first electrode 510 may include indium tin oxide, and a material of the second electrode 520 may include magnesium (chemical symbol: Mg), silver (chemical symbol: Ag), ytterbium (chemical symbol: Yb), etc.

In some embodiments, the donor material 321 and the acceptor material 322 interact with each other to achieve the photoelectric sensing function.

In any of the above embodiments, when the display panel includes a third encapsulation layer 730, a first light shielding layer 630, and filter portions 620, the first light shielding layer 630 and the filter portions 620 may be located on a side of the third encapsulation layer 730 facing away from the second encapsulation layer 720.

Although the present application is described with reference to the preferred embodiments, various modifications can be made, and equivalents can be provided to substitute for the components thereof without departing from the scope of the present application. In particular, the technical features mentioned in the embodiments can be combined in any manner, provided that there is no structural conflict. The present application is not limited to the specific embodiments disclosed herein but includes all the embodiments that fall within the scope of the claims.

1. A display panel, comprising:
a substrate;
an isolation structure disposed on one side of the substrate, the isolation structure enclosing a plurality of isolation openings, the plurality of isolation openings comprising a first isolation opening and a second isolation opening;
a light-emitting sub-pixel comprising a light-emitting structure located in the first isolation opening; and
a photosensitive sub-pixel comprising a photoelectric sensing structure located in the second isolation opening.

2. The display panel according to claim 1, further comprising first electrodes and second electrodes, wherein each of the light-emitting structure and the photoelectric sensing structure is provided with the first electrode on a side facing the substrate, each of the light-emitting structure and the photoelectric sensing structure is provided with the second electrode on a side facing away from the substrate, and the second electrodes are located in the isolation openings and electrically connected to the isolation structure; a thickness of the second electrode located on the side of the light-emitting structure facing away from the substrate is different from a thickness of the second electrode located on the side of the photoelectric sensing structure facing away from the substrate;
the isolation structure comprises a first sublayer and a second sublayer located on a side of the first sublayer facing away from the substrate, an orthographic projection of the first sublayer on the substrate being located within an orthographic projection of the second sublayer on the substrate, and the second electrodes being electrically connected to the first sublayer;
the isolation structure further comprises a third sublayer located on a side of the first sublayer facing the substrate, the orthographic projection of the first sublayer on the substrate being located within an orthographic projection of the third sublayer on the substrate, and the second electrodes being electrically connected to the third sublayer;
at least one of an orthographic projection of the light-emitting structure on the substrate and an orthographic projection of the photoelectric sensing structure on the substrate is spaced apart from the orthographic projection of the third sublayer on the substrate.

3. The display panel according to claim 2, further comprising: an electron blocking layer disposed on the side of the photoelectric sensing structure facing the substrate, the electron blocking layer being divided by the isolation structure into a first section and a second section, the first section being located in the first isolation opening, and the second section being located in the second isolation opening;
the light-emitting sub-pixel further comprises a hole transport layer located on the side of the light-emitting structure facing the substrate, the first section is located between the hole transport layer and the light-emitting structure, and the second section is located between the first electrode and the photoelectric sensing structure;
the display panel further comprises a hole blocking layer disposed on the side of the photoelectric sensing structure facing away from the substrate, the hole blocking layer being divided by the isolation structure into a third section and a fourth section, the third section being located in the first isolation opening, and the fourth section being located in the second isolation opening;
the light-emitting sub-pixel further comprises an electron transport layer on the side of the light-emitting structure facing away from the substrate, the third section is located between the electron transport layer and the light-emitting structure, and the fourth section is located between the second electrode and the photoelectric sensing structure.

4. The display panel according to claim 2, wherein: the first electrode corresponding to the light-emitting structure is configured to transmit a first voltage VL-E, the second electrode corresponding to the light-emitting structure is configured to transmit a second voltage VU-E, the first electrode corresponding to the photoelectric sensing structure is configured to transmit a third voltage VL-P, and the second electrode corresponding to the photoelectric sensing structure is configured to transmit a fourth voltage VU-P, the first voltage, the second voltage, the third voltage and the fourth voltage satisfying the following relationship:
$$VL - E \geq VU - E = VU - P \geq VL - P ;$$
the light-emitting structure comprises at least one of an organic light-emitting diode material, a quantum dot material, a perovskite material, or a perovskite quantum dot material, and the photoelectric sensing structure comprises at least one of an organic light-emitting diode material, a quantum dot material, a perovskite material, or a perovskite quantum dot material;
the second electrode corresponding to the light-emitting structure is configured to enable transmission of emitted light from the light-emitting structure, and the second electrode corresponding to the photoelectric sensing structure is configured to enable transmission of sensing light from the photoelectric sensing structure;
the first electrode corresponding to the light-emitting structure is configured to enable reflection of the emitted light from the light-emitting unit, and the first electrode corresponding to the photoelectric sensing structure is configured to enable reflection of the sensing light from the photoelectric sensing structure; and
the first electrode comprises a metal oxide layer, a metal layer and a metal oxide layer arranged in a stack.

5. The display panel according to claim 2, further comprising:
a light extraction layer comprising a light extraction portion located on a side of each of the second electrodes facing away from the substrate;
a first encapsulation layer comprising an encapsulation portion located on a side of each of the light extraction portions facing away from the substrate, the plurality of encapsulation portions being disposed separately from each other, and a gap being formed between adjacent encapsulation portions on a side of the isolation structure facing away from the substrate,
the light extraction portions comprise a first light extraction portion located on the side of the light-emitting structure facing away from the substrate and a second light extraction portion located on the side of the photoelectric sensing structure facing away from the substrate, a thickness of the first light extraction portion being different from a thickness of the second light extraction portion.

6. The display panel according to claim 5, wherein each encapsulation portion comprises a first encapsulation segment and a second encapsulation segment, the first encapsulation segment being located in the respective isolation opening, and the second encapsulation segment being connected to a peripheral side of the first encapsulation segment and located on the side of the isolation structure facing away from the substrate;
the light extraction layer further comprises a first dummy segment located between each second encapsulation segment and the isolation structure;
a second dummy segment is further provided between each second encapsulation segment and the isolation structure, the second dummy segment being located between the respective first dummy segment and the isolation structure, and the second dummy segment being of the same material as the light-emitting structure or the photoelectric sensing structure;
a dummy electrode is further provided between each second dummy segment and the respective first dummy segment, the dummy electrode being of the same material as the second electrode; and
a second encapsulation layer located on a side of the first encapsulation layer facing away from the substrate, a material of the second encapsulation layer comprising an organic material; and
a third encapsulation layer located on a side of the second encapsulation layer facing away from the first encapsulation layer, a material of the third encapsulation layer comprising an inorganic material; and
a material of the first encapsulation layer comprising an inorganic material.

7. The display panel according to claim 1, wherein an area of an orthographic projection of the first isolation opening on the substrate is greater than an area of an orthographic projection of the second isolation opening on the substrate;
the isolation structure comprises a first isolation portion which encloses the first isolation opening and a second isolation portion which encloses the second isolation opening, a width of an orthographic projection of at least part of the first isolation portion on the substrate being smaller than a width of an orthographic projection of the second isolation portion on the substrate.

8. The display panel according to claim 1, further comprising: a pixel definition layer disposed on the substrate, wherein the isolation structure is disposed on a side of the pixel definition layer facing away from the substrate, and the pixel definition layer comprises a pixel defining portion and a first opening and a second opening provided in the pixel defining portion, the first opening being in communication with the first isolation opening, the second opening being in communication with the second isolation opening, at least part of the light-emitting structure being located in the first opening, and at least part of the photoelectric sensing structure being located in the second opening; and first electrodes and second electrodes, wherein each of the light-emitting structure and the photoelectric sensing structure is provided with the first electrode on a side facing the substrate, each of the light-emitting structure and the photoelectric sensing structure is provided with the second electrode on a side facing away from the substrate, the pixel defining portion covers a part of the first electrode, and another part of the first electrode is exposed by the first opening and the second opening; and
at least one of the light-emitting structure and the photoelectric sensing structure is defined by the first electrode, the pixel defining portion, and The second electrode is sealed and separated from the isolation structure;
in the first isolation opening and in the first opening located within the first isolation opening, a minimum distance between a wall surface of the pixel defining portion facing the first opening and a wall surface of the isolation structure facing the first isolation opening is defined as a first distance d1, and in the second isolation opening and the second opening located within the second isolation opening, a minimum distance between a wall surface of the pixel defining portion facing the second opening and a wall surface of the isolation structure facing the second isolation opening is defined as a second distance d2, the first distance and the second distance satisfying: 2/3d2≤d1≤3/2d2.

9. The display panel according to claim 1, wherein at least two photosensitive sub-pixels are configured to sense light of different wavelength bands; a photosensitive wavelength band of the photoelectric sensing structure at least partially overlaps a light-emitting wavelength band of the light-emitting structure; the light-emitting sub-pixel comprises a red light-emitting sub-pixel, a green light-emitting sub-pixel, and a blue light-emitting sub-pixel, and the photoelectric sensing structure is configured to sense at least one of red light, green light, and blue light;
or the display panel further comprises a sensing light-emitting sub-pixel configured to emit sensing light, and the photosensitive sub-pixel is configured to sense the sensing light; the sensing light-emitting sub-pixel is configured to emit infrared light, and the photosensitive sub-pixel is configured to sense the infrared light.

10. A display panel, comprising:
a substrate;
a light-emitting sub-pixel disposed on one side of the substrate, the light-emitting sub-pixel comprising a light-emitting structure;
a photosensitive sub-pixel disposed on one side of the substrate, the photosensitive sub-pixel comprising a photoelectric sensing structure, a material of the photoelectric sensing structure comprising a donor material and an acceptor material; and an electron blocking layer disposed on a side of the light-emitting structure and the photoelectric sensing structure facing the substrate, wherein a HOMO energy level of the donor material is lower than or equal to a HOMO energy level of the electron blocking layer.

11. The display panel according to claim 10, wherein the HOMO energy level of the electron blocking layer is higher than or equal to a HOMO energy level of the light-emitting structure; the display panel further comprising: an isolation structure disposed on one side of the substrate, the isolation structure enclosing a plurality of isolation openings, the plurality of isolation openings comprising a first isolation opening and a second isolation opening;
a light-emitting structure located in the first isolation opening; and a photoelectric sensing structure located in the second isolation opening.

12. The display panel according to claim 10, further comprising first electrodes and second electrodes, wherein each of the light-emitting structure and the photoelectric sensing structure is provided with the first electrode on a side facing the substrate, each of the light-emitting structure and the photoelectric sensing structure is provided with the second electrode on a side facing away from the substrate, and the electron blocking layer is located on a side of the first electrodes facing away from the substrate;
the light-emitting sub-pixel further comprises a hole transport layer located on the side of the light-emitting structure facing the substrate, and the electron blocking layer comprises a first section and a second section, the first section being located between the hole transport layer and the light-emitting structure, and the second section being located between the first electrode and the photoelectric sensing structure;
the second section is in contact connection with the first electrode;
a LUMO energy level of the hole transport layer is lower than a LUMO energy level of the electron blocking layer;
a HOMO energy level of the hole transport layer is higher than the HOMO energy level of the electron blocking layer;
the LUMO energy level of the electron blocking layer is higher than a LUMO energy level of the donor material; and
the HOMO energy level of the electron blocking layer is higher than the HOMO energy level of the donor material;
further comprising a hole blocking layer disposed on the side of the light-emitting structure and the photoelectric sensing structure facing away from the substrate, wherein a LUMO energy level of the hole blocking layer is lower than or equal to a LUMO energy level of the donor material.

13. The display panel according to claim 12, wherein the light-emitting sub-pixel further comprises an electron transport layer on the side of the light-emitting structure facing away from the substrate, and the hole blocking layer comprises a third section and a fourth section, the third section being located between the electron transport layer and the light-emitting structure, and the second section being located between the second electrode and the photoelectric sensing structure;
the fourth section is in contact connection with the second electrode;
a LUMO energy level of the electron transport layer is lower than the LUMO energy level of the hole blocking layer;
a HOMO energy level of the electron transport layer is higher than a HOMO energy level of the hole blocking layer;
the LUMO energy level of the hole blocking layer is lower than the LUMO energy level of the acceptor material; and
the HOMO energy level of the hole blocking layer is lower than a HOMO energy level of the acceptor material.

14. The display panel according to claim 12, wherein the photosensitive sub-pixel further comprises an electron extraction layer located between the photoelectric sensing structure and the hole blocking layer;
a LUMO energy level of the electron extraction layer is higher than the LUMO energy level of the hole blocking layer;
a HOMO energy level of the electron extraction layer is higher than a HOMO energy level of the hole blocking layer;
the LUMO energy level of the electron extraction layer is lower than the LUMO energy level of the acceptor material; and
the HOMO energy level of the electron extraction layer is lower than a HOMO energy level of the acceptor material.

15. The display panel according to claim 10, wherein the photosensitive sub-pixel further comprises a hole extraction layer located between the electron blocking layer and the photoelectric sensing structure;
a LUMO energy level of the electron blocking layer is higher than a LUMO energy level of the hole extraction layer;
the HOMO energy level of the electron blocking layer is higher than a HOMO energy level of the hole extraction layer;
the LUMO energy level of the hole extraction layer is lower than a LUMO energy level of the donor material; and
the HOMO energy level of the hole extraction layer is higher than the HOMO energy level of the donor material;
the light-emitting structure comprises a host material and a dopant material, a doping ratio of the dopant material to the host material ranging from 0.01% to 10%;
a ratio of the donor material to the acceptor material ranges from 20/1 to 1/20,
wherein the acceptor material comprises fullerene or a fullerene derivative.

16. A display module, comprising:
the display panel according to claim 1; and filter portions located on a side of the light-emitting sub-pixel and the photosensitive sub-pixel facing away from the substrate, the filter portions comprising a first filter portion and a second filter portion, an orthographic projection of the first filter portion on the substrate at least partially overlapping an orthographic projection of the light-emitting sub-pixel on the substrate, and an orthographic projection of the second filter portion on the substrate at least partially overlapping an orthographic projection of the photosensitive sub-pixel on the substrate,
wherein the second filter portion comprises a first subunit and a second subunit, the first subunit and the second subunit having at least partially different light transmission wavelength bands.

17. The display module according to claim 16, wherein the photosensitive sub-pixel comprises a first photosensitive unit and a second photosensitive unit, an orthographic projection of the first subunit on the substrate at least partially overlapping an orthographic projection of the first photosensitive unit on the substrate, an orthographic projection of the second subunit on the substrate at least partially overlapping an orthographic projection of the second photosensitive unit on the substrate, the first photosensitive unit and the second photosensitive unit having different photosensitive wavelengths, the light transmission wavelength band of the first subunit at least partially overlapping a photosensitive wavelength band of the first photosensitive unit, and the light transmission wavelength band of the second subunit at least partially overlapping a photosensitive wavelength band of the second photosensitive unit;
the display module further comprising, a first light shielding layer enclosing filter openings in which the filter portions are located, wherein the first filter portion corresponding to the light-emitting sub-pixel is configured to transmit at least part of emitted light from the light-emitting sub-pixel; and
the second filter portion corresponding to the photosensitive sub-pixel is configured to transmit at least part of sensing light from the photosensitive sub-pixel.

18. The display module according to claim 16, wherein the first subunit is configured to transmit green light, and the second subunit is configured to transmit red light;
the number m of first subunits and the number n of second subunits satisfy: m≥2n; and
an area of the orthographic projection of the first subunit on the substrate is less than or equal to an area of the orthographic projection of the second subunit on the substrate; or
the first subunit is configured to transmit red light, and the second subunit is configured to transmit infrared light;
the number p of first subunits and the number q of second subunits satisfy: p≤2q; and
an area of the orthographic projection of the first subunit on the substrate is less than or equal to an area of the orthographic projection of the second subunit on the substrate.

19. The display module according to claim 17, wherein the display panel further comprising: an encapsulation layer located on a side of the light-emitting structure and the photoelectric sensing structure facing away from the substrate;
a second light shielding layer located on the side of the encapsulation layer facing away from the substrate, the second light shielding layer comprising a first light shielding opening and a second light shielding opening, an orthographic projection of the first light shielding opening on the substrate at least partially overlapping an orthographic projection of the light-emitting structure on the substrate, an orthographic projection of the second light shielding opening on the substrate at least partially overlapping the orthographic projection of the photoelectric sensing structure on the substrate, and an area of the first light shielding opening being greater than an area of the second light shielding opening,
wherein the second light shielding layer doubles as a touch electrode;
the orthographic projection of the first light shielding opening on the substrate has a polygonal shape; and
the orthographic projection of the second light shielding opening on the substrate has a circular, elliptical, or near-circular shape.

20. The display module according to claim 17, further comprising: a light adjustment layer located on the side of the first light shielding layer facing away from the substrate, the light adjustment layer comprising a first adjustment layer, the first adjustment layer comprising a first adjustment protrusion and a second adjustment protrusion, an orthographic projection of the first adjustment protrusion on the substrate at least partially overlapping an orthographic projection of the light-emitting sub-pixel on the substrate, and an orthographic projection of the second adjustment protrusion on the substrate at least partially overlapping the orthographic projection of the photoelectric sensing structure on the substrate,
a light protection layer disposed on a side of the light adjustment layer facing away from the substrate, a refractive index of the light protection layer being less than a refractive index of the light adjustment layer,
wherein orthographic projections of a plurality of first adjustment protrusions on the substrate at least partially overlap the orthographic projection of the same light-emitting sub-pixel on the substrate;
the second adjustment protrusion is disposed corresponding to the photoelectric sensing structure on a one-to-one basis, and a center of the orthographic projection of the adjustment protrusion on the substrate overlaps a center of the orthographic projection of the photoelectric sensing structure on the substrate; and/or the center of the orthographic projection of the adjustment protrusion on the substrate overlaps a center of the orthographic projection of the second light shielding opening on the substrate; and
wherein, the refractive index of the light adjustment layer is greater than 1.5; and
the refractive index of the light protection layer is less than 1.5.
